(19) United States
(12) Patent Application Publication
(10) Pub. No.: US 2020/0409272 A1
(43) Pub. Date: Dec. 31, 2020

(54) Fabricating Sub-Lithographic Devices

(71) Applicant: SPIN MEMORY, INC., FREMONT, CA (US)

(72) Inventors: Gian Sharma, Fremont, CA (US); Amitay Levi, Cupertino, CA (US)

(21) Appl. No.: 16/452,302

(22) Filed: Jun. 25, 2019

(51) Int. Cl. G03F 7/20

(52) U.S. Cl. CPC G03F 7/70608; G03F 7/708; G03F 7/70625

(57) ABSTRACT

A sub-lithographic device, and a method of fabricating the device, is provided. The method includes determining a lithographic size constraint, and determining size and position of sub-lithographic components of the device. A resist layer is deposited on a substrate, and a mask is positioned over the substrate. The mask includes an aperture corresponding to a first region of the resist layer. After positioning the mask, the resist layer is partially exposed to a radiant energy. The mask is adjusted such that the aperture corresponds to a second region of the resist layer. The overlap of the first region and the second region corresponds to the position of a component of the device. The resist layer is partially exposed again to the radiant energy. An opening is formed in the resist layer by removing fully exposed portion of the resist layer. Subsequently, material for the component is deposited within the opening.

### RELATED APPLICATION

This application is related to U.S. Utility application Ser. No. ****, filed Jun. 25, 2019 [Attorney Docket No. 120331-5028-US], entitled “Fabricating Devices with Reduced Isolation Regions,” which application is incorporated by reference in its entirety.

### TECHNICAL FIELD

This relates generally to the field of memory applications and voltage devices, including but not limited to fabrication of sub-lithographic devices.

### BACKGROUND

In semiconductor manufacturing, smaller size features and/or smaller isolation areas (e.g., regions between neighboring transistors) are needed to increase the layout of devices (e.g., MOS devices). However, conventional techniques limit the size of features that can be fabricated. Photolithography (sometimes called optical lithography) is a fabrication technique that transfers a pattern on a photomask onto a substrate (e.g., a wafer) that is coated with a light sensitive material (e.g., a photoresist) by exposing the light-sensitive material to light (e.g., an ultra-violet light). Photolithography resolution is limited by the diffraction limit of light. Various parameters, such as the wavelength of the light used and numerical aperture, limit the size of devices or features that can be fabricated.

### SUMMARY

Accordingly, there is a need for methods, systems and/or devices for fabricating sub-lithographic devices and/or isolation regions. Such systems, devices, and methods optionally increase active line width and reduce gaps (sometimes called shallow trench isolation or STI) between active areas while maintaining the pitch. The techniques complement or replace conventional systems for fabricating semiconductor devices, such as photolithography and etch tools. The proposed methods use partial exposure photo methods that have higher tolerance to misalignments than conventional techniques. The techniques can be used to fabricate devices with sub-lithographic size features and, in some implementations, provide manifold increase (e.g., 4 to 8 times improvement in some instances) in layout or feature density (sometimes called tool density). In some instances, the techniques can be used to fabricate sub-lithographic feature size components separated by sub-lithographic size gaps. Some implementations use a single mask as opposed to several masks (e.g., masks with distinct sizes) to fabricate sub-lithographic size features and/or isolation regions.

The techniques described herein have a variety of applications. For example, the methods or systems can be used to improve drive current of planar MOS transistors significantly (e.g., by more than 60 percent in some instances) by increasing the gate width of the transistors (e.g., by reducing the STI size). Thus, the techniques can be used to fabricate high performance MOS devices with sub-lithographic size features. As further examples, the techniques described herein can be used to manufacture MTJ pillar patterns, heater elements, contacts or vias, that are smaller than those manufactured using conventional photolithographic techniques. In some implementations, the techniques reduce poly line gate length below photolithographic limits, and help improve density of memory cell architectures (sometimes called memory arrays). In some implementations, the techniques reduce gate length and thereby improve speed of transistors. Some implementations yield the improvements while maintaining a given pitch.

In one aspect, some implementations include a method of fabricating a sub-lithographic device. The method comprises identifying a lithographic size constraint. The method further comprises determining a component size and positioning for a first component of a plurality of components of the sub-lithographic device, including determining that the component size is less than the lithographic size constraint. The position includes a first corner and a second corner diagonally opposed to the first corner. The method further includes depositing a resist layer on a substrate (e.g., a planar substrate). The resist layer has a sensitivity to a radiant energy, and a first exposure time (sometimes called a first full exposure time or a full exposure time in reference to a time required to fully expose the resist layer to the radiant energy). The positioning for the first component corresponds to a first portion of the resist layer. The method further comprises positioning a first mask over the substrate, the first mask including a first aperture corresponding to a first region of the resist layer aligned with the first corner. The first region includes the first portion and has a size larger than the component size. The method also includes, after positioning the first mask, exposing the resist layer to the radiant energy for a first time, less than the first exposure time, to partially expose the first region. In some implementations, the method further comprises selecting the first time to be at least half of the first exposure time.

The method further comprises adjusting positioning of the first mask with respect to the substrate such that the first aperture in the first mask corresponds to a second region of the resist layer aligned with the second corner, the second region partially overlapping the first region. The overlap of the first region and the second region is the first portion of the resist layer. In some implementations, adjusting positioning of the first mask comprises one or more of: stepping the first mask along a first axis, and stepping the first mask along a second axis. The method further includes, after adjusting the positioning of the first mask, exposing the resist layer to the radiant energy for a second time, less than the first exposure time. The sum of the first time and the second time is equal to, or greater than, the first exposure time such that, after exposing for the first time and the second time, the first portion of the resist layer is fully exposed to the radiant energy. The method further includes forming an opening in the resist layer by removing the fully exposed first portion of the resist layer, and depositing material for the first component within the opening in the resist layer. In some implementations, removing the fully exposed resist region is performed by using a developer solution.

In some implementations, the method further includes identifying a minimum pitch based on the lithographic size constraint, determining a second pitch, greater than the minimum pitch, based on the component size and positioning of each of the plurality of components. The second pitch is selected to prevent undesirable overlap when adjusting the positioning of the first mask, and generating the first mask based on the second pitch.

In some implementations, the method further comprises producing the first mask for fabrication of a plurality of sub-lithographic devices, including the sub-lithographic device. The method further comprises associating the first aperture in the first mask to the sub-lithographic device. The method also includes associating a second aperture in the first mask to a second sub-lithographic device, distinct from the sub-lithographic device. The method further includes determining a first area of the resist layer that will be at least partially exposed via the first aperture and adjustments to the first mask positioning during fabrication of the plurality of components. The method also includes determining a second area of the resist layer that will be at least partially exposed via the second aperture and the adjustments to the first mask during fabrication of a second plurality of components for the second sub-lithographic device. The method also includes determining a pitch for the first mask based on a spacing between the plurality of sub-lithographic devices, the pitch sufficient to prevent overlap of the first area and the second area, and generating the first mask with the first aperture, the second aperture, and the determined pitch.

In some implementations, the method further comprises depositing a hard mask layer, such that cavities are not formed in partially exposed regions of the resist layer.

In some implementations, the method further includes prior to depositing the resist layer, depositing a dielectric layer over the substrate. The method also includes, after forming the opening in the resist layer, etching a corresponding opening in the dielectric layer, and removing the remaining resist layer. Depositing the material comprises depositing the material in the opening of the dielectric layer.

In some implementations, the method further comprises determining a component size and positioning for a second component of the plurality of components. The positioning for the second component corresponds to a second portion of the resist layer. The method also includes removing the first mask and positioning a second mask over the substrate, the second mask including a third aperture corresponding to a third region of the resist layer, the third region including the second portion and having a size larger than the component size for the second component, and after positioning the second mask, exposing the resist layer to the radiant energy for a third time, less than the first exposure time, to partially expose the third region.

In another aspect, a sub-lithographic device is provided. The device includes a plurality of components, including a first component fabricated by any of the methods described herein.

In another aspect, a method of fabricating a sub-lithographic phase change device is provided. The method includes identifying a lithographic size constraint. The method also includes determining a component size and positioning, for a first phase change component, including determining that the component size is less than the lithographic size constraint. The method further includes obtaining a substrate with a dielectric layer a resist layer stacked on top. The resist layer has a sensitivity to a radiant energy with a first exposure time. The positioning for the first phase change component corresponds to a first portion of the resist layer. The method further includes exposing a first region of the resist layer to the radiant energy for a first time, less than the first exposure time, to partially expose the first region. The method further comprises exposing a second region of the resist layer to the radiant energy for a second time, less than the first exposure time. The second region partially overlaps with the first region such that the overlap of the first region and the second region is the first portion. The sum of the first time and the second time is equal to, or greater than, the first exposure time such that, after exposing for the first time and the second time, the first portion of the resist layer is fully exposed to the radiant energy. The method also includes forming a first opening in the resist layer by removing the fully exposed first portion of the resist layer. The method further includes forming a first opening in the dielectric layer by removing a portion of the dielectric layer corresponding to the first opening in the resist layer. The method further includes creating the first phase change component within the first opening in the dielectric layer. The first phase change component changes phase at a predetermined phase-change temperature.

In some implementations, creating the first phase change component comprises depositing one or more materials corresponding to the first phase change component within the first opening in the dielectric layer. A volume of the one or more materials affects power requirements for the first phase change component.

In some implementations, creating the first phase change component comprises depositing a first material within the first opening in the dielectric layer; and depositing a second material over the first material within the first opening in the dielectric layer. In some implementations, the first material and the second material have different electrical resistances. In some implementations, the first material is a heater element configured to heat the second material, and the second material is a phase change resistor configured to transition from a first phase to a second phase at the predetermined phase change temperature. The phase change resistor has a first resistance (e.g., a few MΩ) while in the first phase and a second resistance (e.g., a few 1) different from the first resistance while in the second phase.

In some implementations, the method further comprises creating a second phase change component of the sub-lithographic phase change device by performing a sequence of steps. The sequence of steps includes determining a second component size and positioning for the second phase change component, including determining that the second component size is less than the lithographic size constraint. The position includes a third corner and a fourth corner diagonally opposed to the third corner. The positioning for the second phase change component corresponds to a second portion of the resist layer. The sequence of steps also includes positioning the first mask over the substrate, the first mask including a second aperture corresponding to a third region of the resist layer aligned with the third corner, the third region including the second portion and having a size larger than the second component size. The sequence of steps further includes, after positioning the first mask, exposing the resist layer to the radiant energy for a third time, less than the first exposure time, to partially expose the third region. The sequence of steps includes adjusting positioning of the first mask with respect to the substrate such that the second aperture in the first mask corresponds to a fourth region of the resist layer aligned with the fourth corner. The fourth region partially overlaps the third region, and the overlap of the third region and the fourth region is the second portion of the resist layer. The sequence of steps also includes, after adjusting the positioning of the first mask, exposing the resist layer to the radiant energy for a fourth time, less than the first exposure time. The sum of the first time and the second time is equal to, or greater than, the first exposure time such that, after exposing for the second time and the fourth time, the second portion of the resist layer is fully exposed to the radiant energy. The sequence of steps also includes forming a second opening in the resist layer by removing the fully exposed second portion of the resist layer, forming a second opening in the dielectric layer by removing a portion of the dielectric layer corresponding to the second opening in the resist layer, and creating the second phase change component within the second opening in the dielectric layer.

In some implementations, the first component is larger than the second component, thereby having different phase change properties. In some implementations, creating the first component and the second component comprises depositing a first material within the first opening and the second opening, and, after depositing the first material, depositing a second material within the first opening and the second opening. The first component has a different ratio of the first material to the second material than the second component.

In some implementations, the method further includes electrically coupling the second material of the first component to a top electrode positioned over the first component.

In some implementations, the method further comprises electrically coupling the first material of the first component to a bottom electrode.

In another aspect, a method is provided for fabricating a plurality of devices with reduced isolation regions there between. The method comprises obtaining a substrate with a dielectric layer and a resist layer stacked thereupon. The resist layer has a sensitivity to a radiant energy, and the resist layer has a first exposure time. The method includes identifying a plurality of device locations on the substrate corresponding to the plurality of devices. The plurality of device locations are separated from one another by a plurality of isolation regions such that the plurality of devices is electrically insulated from one another. The plurality of isolation regions includes a first set of rows and a first set of columns. The first set of columns is substantially perpendicular to the first set of rows. A width or a dimension of each column is less than the lithographic size constraint, and width or a dimension of each row is less than the lithographic size constraint. The method further comprises fabricating the plurality of isolation regions, including by positioning a first mask over the substrate. The method further comprises, after positioning the first mask, exposing the resist layer to the radiant energy for a first time, less than the first exposure time, to partially expose the resist layer. In some implementations, the method further comprises selecting the first time to be at least half of the first exposure time.

The method further comprises adjusting positioning of the first mask with respect to the substrate along a first axis. The method further comprises, after adjusting the positioning of the first mask along the first axis, exposing the resist layer to the radiant energy for a second time, less than the first exposure time. The sum of the first time and the second time is equal to, or greater than, the first exposure time such that, after exposing for the first time and the second time, the first set of columns of the resist layer is fully exposed to the radiant energy. The method further comprises adjusting positioning of the first mask with respect to the substrate along a second axis that is substantially perpendicular to the first axis. The method further comprises, after adjusting the positioning of the first mask along the second axis, exposing the resist layer to the radiant energy for a third time, less than the first exposure time. The sum of the first time and the third time is equal to, or greater than, the first exposure time such that, after exposing for the first time and the third time, the first set of rows of the resist layer is fully exposed to the radiant energy. The method further comprises removing fully exposed portions of the resist layer including the first set of rows and the first set of columns. The method further comprises forming row and column openings in the substrate by removing portions of the dielectric layer and the substrate corresponding to the fully exposed portions of the resist layer. In some implementations, removing the fully exposed portions of the resist layer is performed by using a developer solution. In some implementations, the substrate is planar.

The method further comprises creating sub-lithographic isolation regions by depositing a dielectric material in the row and column openings in the substrate.

In some implementations, obtaining the substrate with the dielectric layer and the resist layer comprises depositing the dielectric layer over the substrate, and depositing the resist layer over the dielectric layer.

In some implementations, prior to depositing the resist layer, depositing a protective layer over the dielectric layer such that cavities are not formed in partially exposed regions of the resist layer, and removing the protective layer after depositing the dielectric material in the row and column openings in the substrate.

In some implementations, the dielectric material deposited in the row and column openings in the substrate corresponds to a material of the dielectric layer.

In some implementations, the method further comprises depositing a material corresponding to the dielectric layer in the row and column openings in the substrate prior to depositing the dielectric material.

In some implementations, the lithographic size constraint corresponds to a first isolation width, and each of the plurality of isolation regions has a width that is less than the first isolation width.

In some implementations, the method further comprises polishing of the dielectric material deposited in the row and column openings in the substrate.

In some implementations, the method further comprises, after fabricating the plurality of isolation regions: depositing a second resist layer having a second exposure time. The method includes fabricating respective sub-lithographic elements for each of the plurality of devices, comprising a sequence of steps for each device of the plurality of devices. The sequence of steps includes determining an element size and positioning for the sub-lithographic element. The position includes a first corner and a second corner diagonally opposed to the first corner. The positioning for the sub-lithographic element corresponds to a first portion of a second resist layer. The sequence of steps also includes positioning a second mask over the substrate, the second mask including a first aperture corresponding to a first region of the second resist layer aligned with the first corner, the first region including the first portion and having a size larger than the element size. The sequence of steps further includes after positioning the first mask, exposing the second resist layer to the radiant energy for a fourth time, less than the second exposure time, to partially expose the first region. The sequence of steps further includes adjusting positioning of the second mask with respect to the substrate such that the first aperture in the second mask corresponds to a second region of the second resist layer aligned with the second corner, the second region partially overlapping the first region. The overlap of the first region and the second region is the first portion. The sequence of steps further includes, after adjusting the positioning of the second mask, exposing the second resist layer to the radiant energy for a fifth time, less than the second exposure time. The sum of the fourth time and the fifth time is equal to, or greater than, the second exposure time such that, after exposing for the fourth time and the fifth time, the first portion of the second resist layer is fully exposed to the radiant energy. The sequence of steps further includes forming an opening in the second resist layer by removing the fully exposed first portion, and depositing material for the sub-lithographic element within the opening in the second resist layer.

In another aspect, a plurality of devices is provided. The plurality of devices includes a plurality of reduced isolation regions there between, including a first reduced isolation region fabricated by any of the methods described herein.

In another aspect, a method is provided for fabricating a plurality of sub-lithographic devices. The method comprises identifying a lithographic size constraint. The method further comprises obtaining a substrate with a dielectric layer. The method further comprises fabricating a plurality of sub-lithographic isolation regions. Each sub-lithographic isolation region has a dimension that is less than the lithographic size constraint. The plurality of isolation regions is configured to electrically-insulate the plurality of sub-lithographic devices from one another. The method further comprises fabricating a metal sub-lithographic component for a respective sub-lithographic device. The metal sub-lithographic component has a dimension that is less than the lithographic size constraint, and fabricating a plurality of sub-lithographic poly-gate components by performing a sequence of steps. The sequence of steps comprises depositing a poly layer over the dielectric layer. The sequence of steps further comprises depositing a first resist layer over the poly layer. The first resist layer consists of first regions, second regions, and third regions. The third regions correspond to respective poly-gate components. The sequence of steps further comprises exposing the first regions of a first resist layer, exposing the second regions of the first resist layer, forming openings in the first resist layer by removing fully-exposed regions of the first resist layer, and forming the poly-gate components by removing portions of the poly layer that correspond to the openings in the first resist layer. In some implementations, removing the portions of the poly layer is performed by etching the poly layer.

In some implementations, fabricating the plurality of isolation regions comprises depositing a second resist layer over the substrate, identifying the plurality of sub-lithographic isolation regions comprising a first set of rows and a first set of columns, partially exposing first regions of the second resist layer, partially exposing second regions of the second resist layer. The overlap between the first regions and the second regions of the second resist layer is the first set of columns. Partially exposing the first regions of the second resist layer and partially exposing the second regions of the second resist layer comprises fully exposing the first set of columns. Fabricating the plurality of isolation regions further comprises partially exposing third regions of the second resist layer. Overlap between the first regions and the third regions of the second resist layer is the first set of rows, and partially exposing the first regions of the second resist layer and partially exposing the third regions of the second resist layer comprises fully exposing the first set of rows. Fabricating the plurality of isolation regions further comprises removing fully exposed portions of the second resist layer including the first set of rows and the first set of columns, forming row and column openings in the substrate by removing portions of the dielectric layer and the substrate corresponding to the removed portions of the second resist layer, and creating the plurality of sub-lithographic isolation regions by depositing a dielectric material in the row and column openings in the substrate.

In some implementations, the second resist layer has sensitivity to a radiant energy and has a first exposure time, partially exposing first regions of the second resist layer comprises exposing the second resist layer to the radiant energy for a first time, less than the first exposure time, partially exposing second regions of the second resist layer comprises exposing the second resist layer to the radiant energy for a second time, less than the first exposure time, partially exposing third regions of the second resist layer comprises exposing the second resist layer to the radiant energy for a third time, less than the first exposure time. The sum of the first time and the second time is equal to, or greater than, the first exposure time such that, after exposing for the first time and the second time, the first set of columns of the second resist layer is fully exposed to the radiant energy. The sum of the first time and the third time is equal to, or greater than, the first exposure time such that, after exposing for the first time and the third time, the first set of rows of the second resist layer is fully exposed to the radiant energy.

In some implementations, the method further comprises selecting the first time to be at least half of the first exposure time. In some implementations, the method further comprises, prior to depositing the second resist layer, depositing a protective layer the dielectric layer such that cavities are not formed in partially exposed regions of the second resist layer, and removing the protective layer after depositing the dielectric material in the row and column openings in the substrate.

In some implementations, fabricating the metal sub-lithographic component comprises depositing a third resist layer over the dielectric layer, partially exposing a first region of the third resist layer, partially exposing a second region of the third resist layer. The overlap between the first region and the second region of the third resist layer is a first portion that corresponds to the metal sub-lithographic component. Partially exposing the first region of the third resist layer and partially exposing the second region of the third resist layer comprises fully exposing the first portion. Fabricating the metal sub-lithographic component further comprises forming an opening in the third resist layer by removing the fully exposed first portion, forming a component opening in the dielectric layer by removing portions of the dielectric layer corresponding to the opening in the third resist layer, and depositing material for the metal sub-lithographic component within the component opening in the dielectric layer.

In some implementations, the method further comprises determining a component size and positioning for the metal sub-lithographic component, including determining that the component size is less than the lithographic size constraint. The position includes a first corner and a second corner diagonally opposed to the first corner.

In some implementations, partially exposing the first region of the third resist layer comprises positioning a first mask over the substrate, the first mask including a first aperture corresponding to the first region of the third resist layer aligned with the first corner, the first region including the first portion and having a size larger than the component size. Partially exposing the first region of the third resist layer further comprises, after positioning the first mask, exposing the third resist layer to a radiant energy for a first time, less than a first exposure time, to partially expose the first region. The third resist layer has a sensitivity to the radiant energy, and the third resist layer has the first exposure time. Partially exposing the first region of the third resist layer further comprises adjusting positioning of the first mask with respect to the substrate such that the first aperture in the first mask corresponds to the second region of the third resist layer aligned with the second corner, and, after adjusting the positioning of the first mask, exposing the third resist layer to the radiant energy for a second time, less than the first exposure time. The sum of the first time and the second time is equal to, or greater than, the first exposure time such that, after exposing for the first time and the second time, the first portion of the resist layer is fully exposed to the radiant energy.

In some implementations, the method further comprises identifying a minimum pitch based on the lithographic size constraint, determining a second pitch, greater than the minimum pitch, based on a size and positioning of the metal sub-lithographic component. The second pitch is selected to prevent undesirable overlap when adjusting the positioning of the first mask, and generating the first mask based on the second pitch.

In another aspect, a sub-lithographic device is provided. The sub-lithographic device comprises a plurality of poly-gate components, including a first component. The first component is fabricated by a method comprising identifying a lithographic size constraint. The method further comprises obtaining a substrate with a dielectric layer thereon, depositing a poly layer over the dielectric layer, depositing a first resist layer over the poly layer, partially exposing first regions of a first resist layer, partially exposing second regions of the first resist layer. The overlap between the first regions and the second regions of the first resist layer are first portions that correspond to respective poly-gate components of the plurality of poly-gate components. Partially exposing the first regions of the first resist layer and partially exposing the second regions of the first resist layer comprises fully exposing the first portions. The method further comprises forming openings in the first resist layer by removing the fully exposed first portions of the first resist layer, and forming the poly-gate components by removing portions of the poly layer that correspond to the openings in the first resist layer.

Thus, devices and systems are provided with methods for fabricating sub-lithographic devices and/or isolation regions there between (e.g., between sub-lithographic components and/or sub-lithographic devices), thereby increasing the density of components and/or devices.

### BRIEF DESCRIPTION OF THE DRAWINGS

For a better understanding of the various described implementations, reference should be made to the Description of Implementations below, in conjunction with the following drawings in which like reference numerals refer to corresponding parts throughout the figures.

FIG. 1A shows a schematic diagram of a representative layout for fabricating devices in accordance with some implementations.

FIGS. 1B-1D illustrate a representative process for fabricating sub-lithographic devices, according to some implementations.

FIG. 2A shows a schematic diagram of a representative layout for fabricating devices in accordance with some implementations.

FIGS. 2B-2E illustrate a representative process for fabricating sub-lithographic devices in accordance with some implementations.

FIG. 3A shows a schematic diagram of a representative layout for fabricating devices in accordance with some implementations.

FIGS. 3B-3F illustrate a representative process for fabrication that improves tool density in accordance with some implementations.

FIG. 3G illustrates a schematic diagram of a representative process for fabricating sub-lithographic devices via multiple partial exposures in accordance with some implementations.

FIGS. 4A-4I illustrate a representative process for fabricating sub-lithographic devices in accordance with some implementations.

FIGS. 5A-5I illustrate a representative process for fabricating sub-lithographic devices using a negative photoresist in accordance with some implementations.

FIG. 6 illustrates a representative process for fabricating lithographic devices using a hard mask layer to prevent cavity formation in partial exposed regions of a resist layer in accordance with some implementations.

FIG. 7 illustrates a flowchart of a method for fabricating sub-lithographic devices in accordance with some implementations.

FIGS. 8A-8C illustrate a representative process for fabricating a sub-lithographic phase change device in accordance with some implementations.

FIG. 9 illustrates a representative sub-lithographic phase change device in accordance with some implementations.

FIG. 10 illustrates a flowchart of a method for fabricating sub-lithographic devices in accordance with some implementations.

FIG. 11 illustrates a sectional view of a representative layout for fabricating devices with reduced isolation regions there between, in accordance with some implementations.

FIGS. 12A-12E show schematic diagrams of a representative layout for fabricating devices with reduced isolation regions there between, in accordance with some implementations.

FIGS. 13A and 13B illustrate a flowchart of a method for fabricating devices with reduced isolation regions there between in accordance with some implementations.

FIG. 14 shows a schematic diagram of a representative layout for fabricating a plurality of sub-lithographic devices with reduced isolation regions there between in accordance with some implementations.

FIGS. 15A-15E illustrate a representative process for fabricating a plurality of sub-lithographic devices with reduced isolation regions there between in accordance with some implementations.

FIG. 16 illustrates a flowchart of a method for fabricating a plurality of sub-lithographic devices with reduced isolation regions there between in accordance with some implementations.

Like reference numerals refer to corresponding parts throughout the several views of the drawings.

### DETAILED DESCRIPTION

Reference will now be made in detail to implementations, examples of which are illustrated in the accompanying drawings. In the following detailed description, numerous specific details are set forth in order to provide a thorough understanding of the various described implementations. However, it will be apparent to one of ordinary skill in the art that the various described implementations may be practiced without these specific details. In other instances, well-known methods, procedures, components, circuits, and networks have not been described in detail so as not to unnecessarily obscure aspects of the implementations.

Representative Layout and Processes for Fabricating Sub-Lithographic Devices

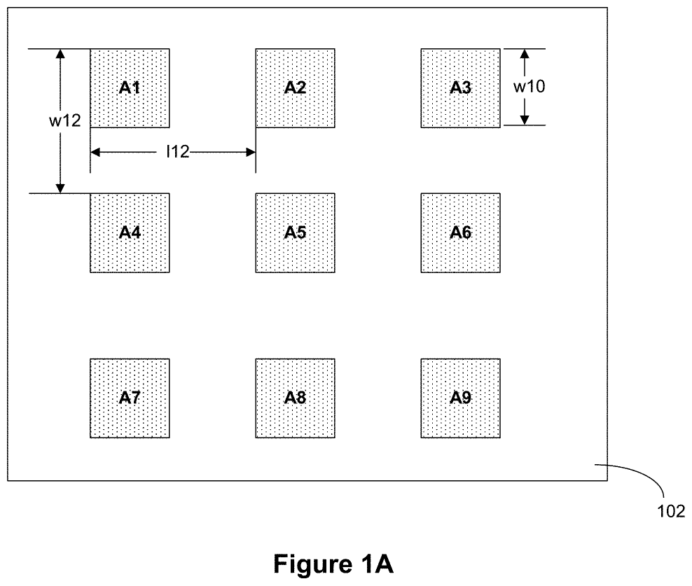

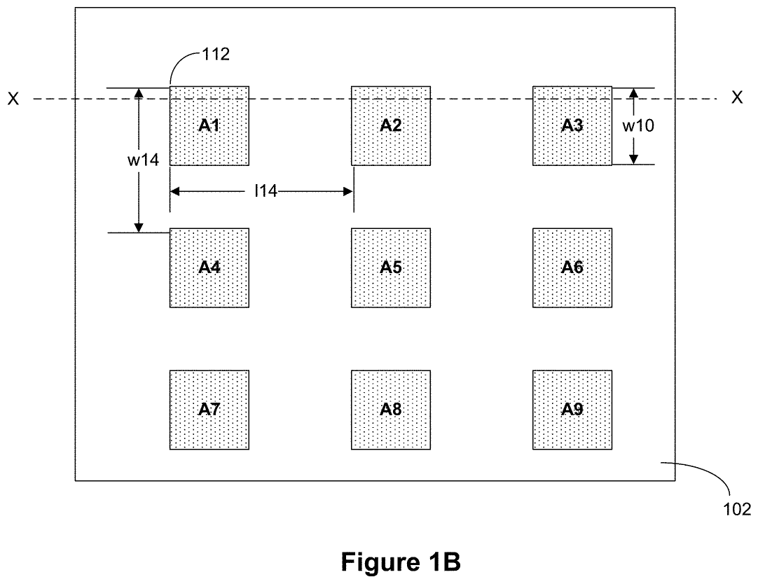

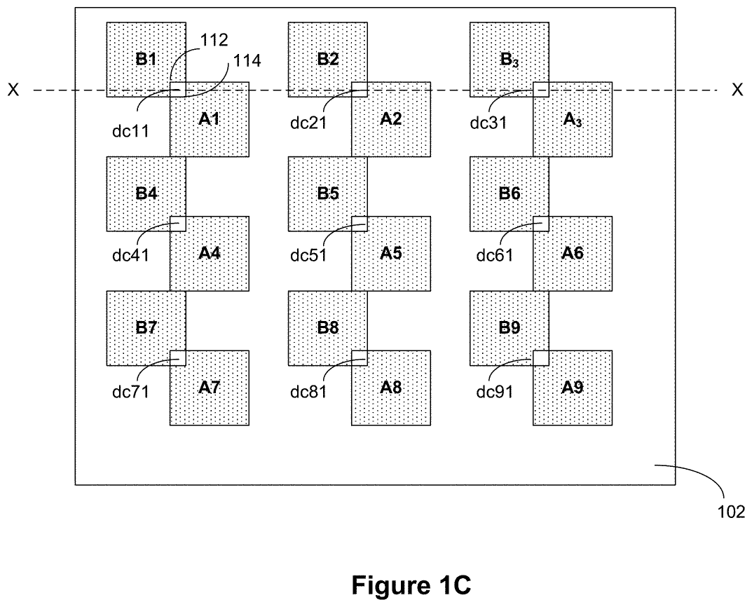

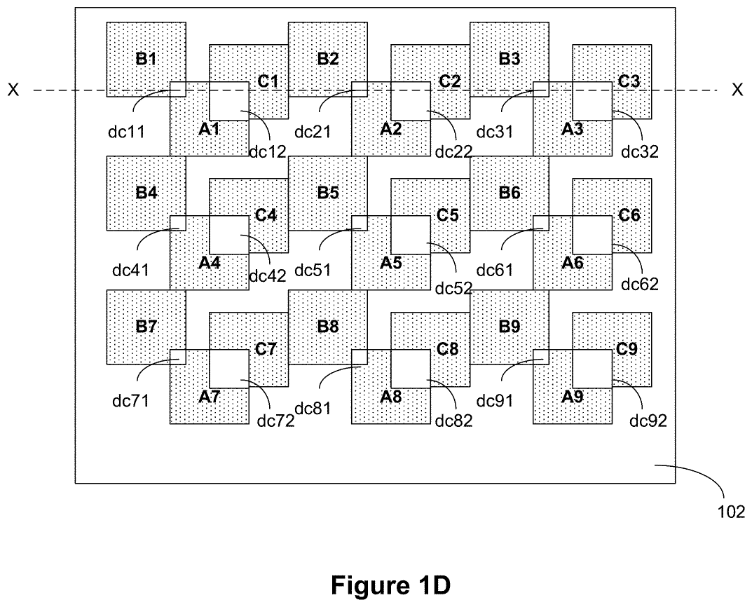

FIG. 1A shows a schematic diagram of a representative layout for fabricating devices in accordance with some implementations. A mask is placed over a resist layer 102. The mask is a conventional photomask (e.g., a glass plate with a pattern etched into an opaque surface). Some implementations use a reticle, a special type of photomask. In some implementations, a reticle is loaded into a stepper or scanner system and a wafer (e.g., a substrate with a resist layer) placed below the reticle is subsequently exposed to a radiant energy passed through the reticle.

In FIG. 1A, the mask is indicated by apertures A1, A2, . . . , A9. The mask has a pitch indicated by length l12 that corresponds to a distance between adjacent apertures along a first axis, and width w12 that corresponds to a distance between adjacent apertures along a second axis that is (substantially) perpendicular to the first axis. Each aperture is typically square-shaped, and substantially equal in size to other apertures of the mask. Each aperture corresponds to a location of a lithographic feature or a device that can be fabricated using the layout, so the aperture size is sometimes called a feature size. In FIG. 1A, the size of each aperture (i.e., length and width of each aperture) is indicated by w10. An example pitch (sometimes called a call) is 130 nm by 130 nm (i.e., l12 is equal to 130 nm and w12 is equal to 130 nm), and aperture size is 65 nm (i.e., w10 is equal to 65 nm), according to some implementations. FIG. 1A shows apertures indicated by A1, A2, and A3 in a first row, apertures indicated by A4, A5, and A6 in a second row, and apertures indicated by A7, A8, and A9 in a third row.

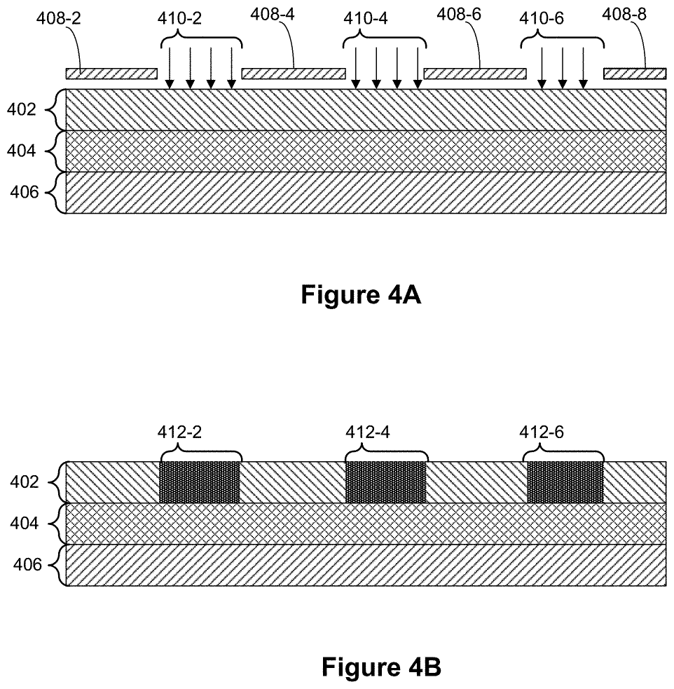

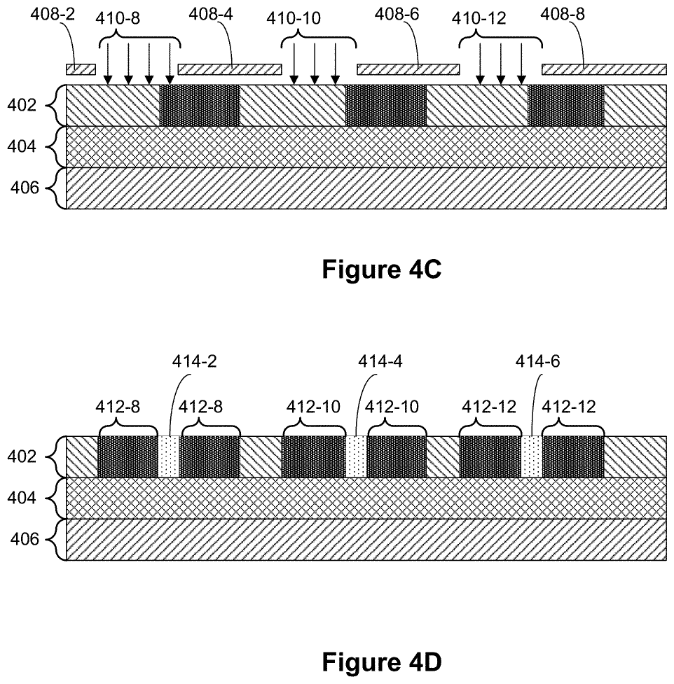

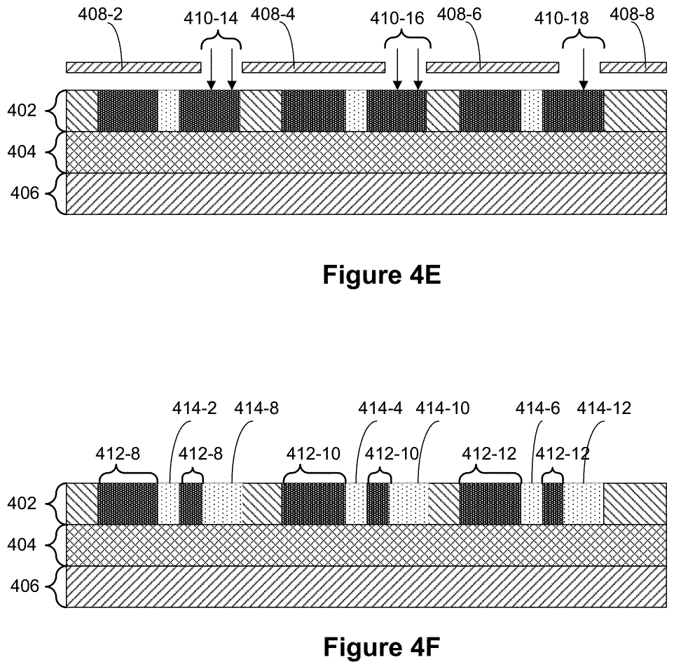

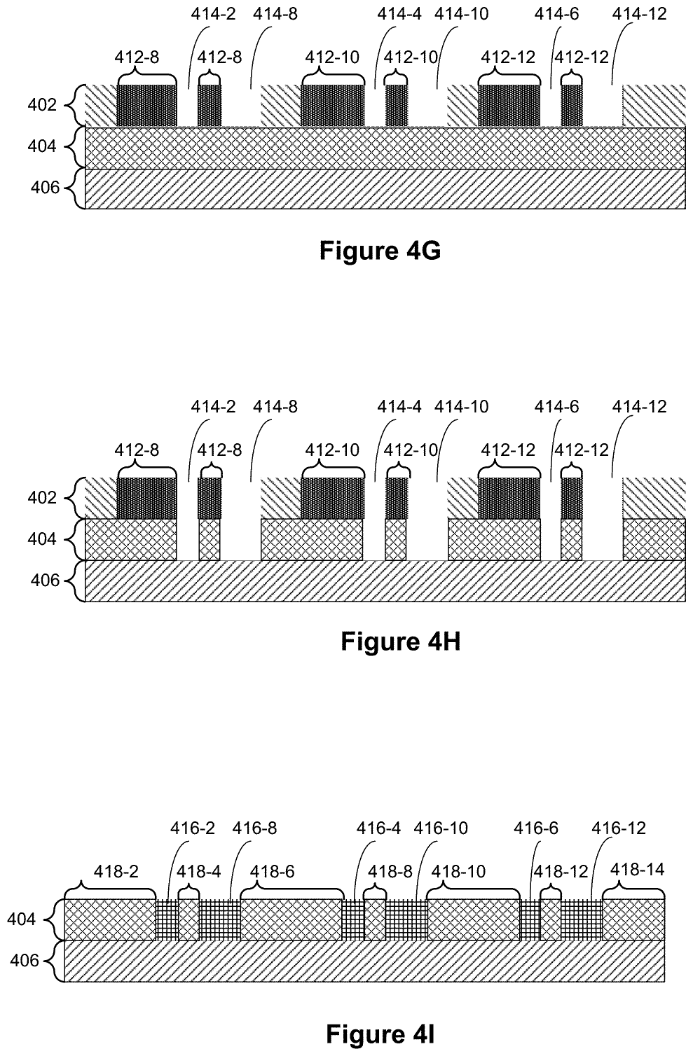

FIGS. 1B-1D illustrate a representative process for fabricating sub-lithographic devices (each device with two sub-lithographic components; e.g., two phase change resistors) starting with the layout in FIG. 1A in accordance with some implementations. Starting with the layout in FIG. 1A, the pitch size is adjusted to match a desired distance between adjacent sub-lithographic devices. In FIG. 1B, relative to FIG. 1A, the length between adjacent apertures along each row is adjusted from l12 to l14, and the width between adjacent apertures along each column is adjusted from w12 to w14. For example, length l14 is adjusted from 130 nm down to 110 nm, and width w14 is adjusted from 130 nm up to 135 nm. In various implementations, the pitch adjustment is effected by choosing or manufacturing a different mask or by adjusting the location of apertures in a given mask to match the desired pitch. As indicated in FIG. 1B, the aperture size (i.e., w10) does not vary. In some implementations, different aperture sizes are selected, in addition to varying the pitch size. Also, the mask is positioned such that a respective corner of each aperture is aligned with a respective (desired) position (on the resist layer 102) of a respective sub-lithographic device component. For example, as indicated, aperture indicated by A1 is positioned such that a corner of the aperture aligns with a desired position of a sub-lithographic device component (indicated by position 112 for device component dc11 in FIG. 1C). In some implementations, each aperture position (characterized by its corners) aligns with desired positions of a respective plurality of device components. For example, position of aperture indicated by A1 aligns with desired positions of components dc11 and dc12 (described below in reference to FIGS. 1C and 1D). As described below in reference to FIG. 4A, the resist layer 102 is partially exposed to a radiant energy via apertures indicated by A1, A2, . . . , A9 in FIG. 1B. As a result, regions on the resist layer 102 that correspond to the apertures are partially exposed.

In FIG. 1C, the mask position is adjusted such that position of each aperture is changed from a first position to a second position. For example, the position of the aperture indicated by A1 is adjusted to a position indicated by B1, the position of the aperture indicated by A2 is adjusted to a position indicated by B2, and so on. In various implementations, this adjustment is effected by moving the mask along a first axis (e.g., after calculating a desired distance along the first axis) and, subsequently, along a second axis substantially perpendicular to the first axis. The mask position is adjusted such that a respective corner of each aperture (e.g., a corner opposite to the one described above in reference to FIG. 1B) is aligned with the respective (desired) position (on the resist layer 102) of the respective sub-lithographic device component. For example, as indicated, aperture indicated by B1 is positioned such that a corner of the aperture aligns with a desired position of the sub-lithographic device component (indicated by position 114 for device component dc11 in FIG. 1C). As described below in reference to FIG. 4C, the resist layer 102 is partially exposed (for a second time) to a radiant energy via apertures indicated by B1, B2, . . . , B9 in FIG. 1C. As a result, regions on the resist layer 102 that correspond to the apertures are partially exposed. This second exposure results in full exposure in some regions of the resist layer 102. For example, in FIG. 1C, the region corresponding to the desired position of device component dc11 is fully exposed after the two exposures. In some implementations, a different mask, with aperture positions indicated by B1, B2, . . . , B9, is used, instead of adjusting the mask in FIG. 1B.

FIG. 1D further illustrates this process for fabricating a second device component (e.g., device components dc12, dc22, dc92) corresponding to each sub-lithographic device (described above in reference to FIG. 1C), according to some implementations. Similar to FIG. 1C, the mask position is adjusted such that the aperture indicated by B1 is shifted to C1, the aperture indicated by B2 is shifted to C2, and so on. Again, each aperture position is adjusted such that a respective corner (e.g., a different corner than the ones described above in reference to FIGS. 1B and 1C) is aligned with a desired position (or a corner) a second respective device component on the resist layer 102. For example, in FIG. 1D, A1 and C1 align with opposite (desired) corners of device component dc12, A2 and C2 align with opposite (desired) corners of device component dc22, and so on.

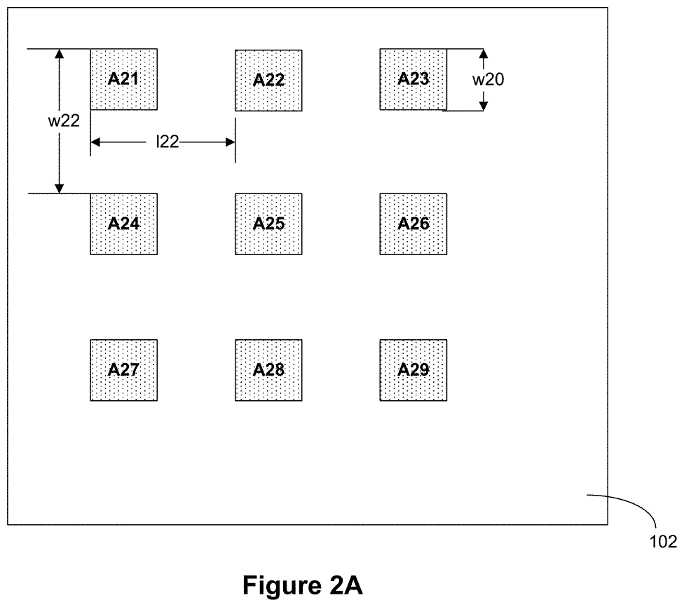

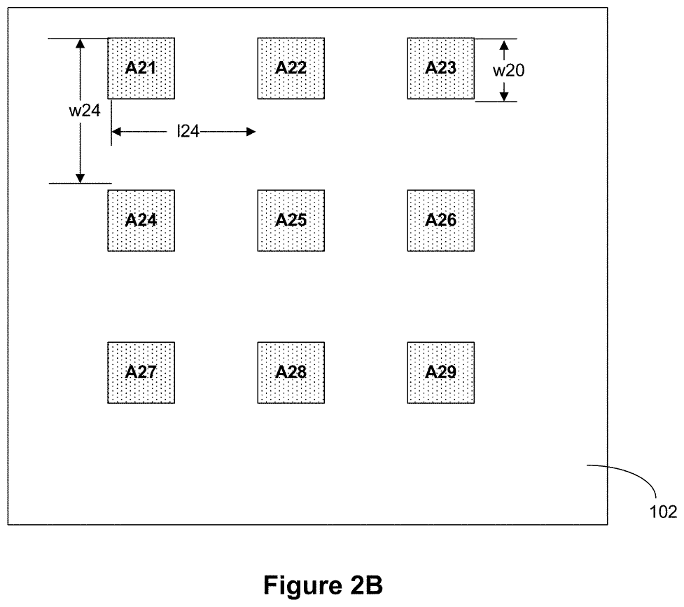

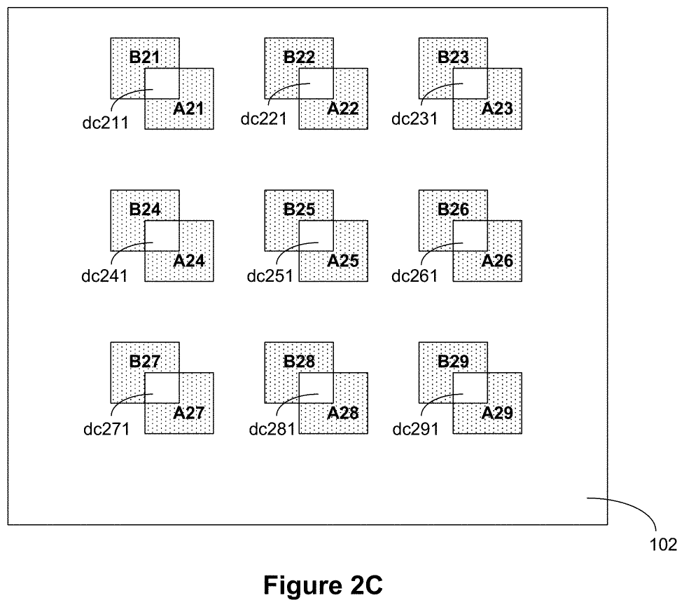

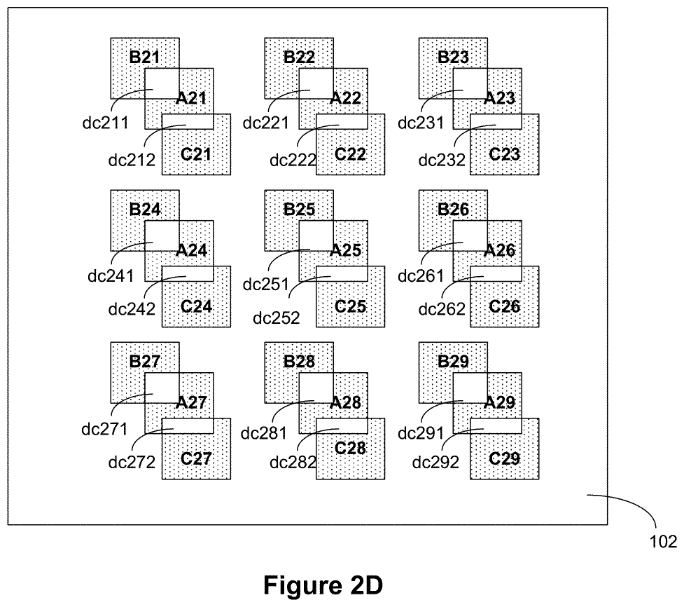

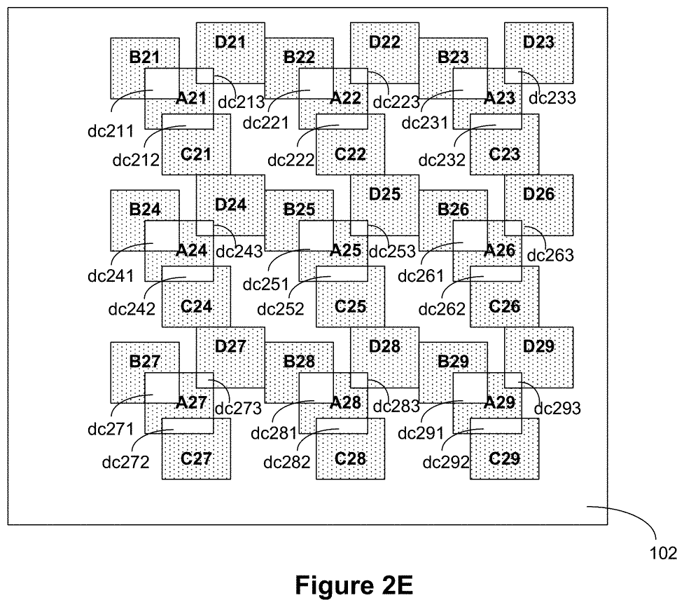

FIG. 2A shows a schematic diagram of another representative layout for fabricating devices in accordance with some implementations. Similar to FIG. 1A, a mask, indicated by apertures A21, A22, . . . , A29, is placed over the resist layer 102. The mask has a pitch indicated by length 122 that corresponds to a distance between adjacent apertures along a first axis, and width w22 that corresponds to a distance between adjacent apertures along a second axis that is (substantially) perpendicular to the first axis. In FIG. 2A, the size of each aperture (i.e., length and width of each aperture) is indicated by w20. An example pitch is 130 nm by 130 nm (i.e., 122 is equal to 130 nm and w22 is equal to 130 nm), and aperture size is 65 nm (i.e., w20 is equal to 65 nm), according to some implementations. FIG. 2A shows apertures indicated by A21, A22, and A23 in a first row, apertures indicated by A24, A25, and A26 in a second row, and apertures indicated by A27, A28, and A29 in a third row. FIG. 2A is similar to FIG. 1A with the starting pitch of the mask indicated by width w22 (e.g., 130 nm) and length 122 (e.g., 130 nm), and the aperture size of the mask indicated by w20 (e.g., 65 nm). The layout (e.g., the number of apertures, aperture sizes, as well as the pitch size) of the mask is selected to match the desired size of sub-lithographic devices.

FIGS. 2B-2E illustrate a representative process for fabricating sub-lithographic devices (each device with three sub-lithographic components; e.g., three phase change resistors) starting with the layout in FIG. 2A in accordance with some implementations. FIG. 2B, similar to FIG. 1B, illustrates an adjustment to the pitch starting with the layout shown in FIG. 2A, according to some implementations. In FIG. 2B, relative to FIG. 2A, the length between adjacent apertures along each row is adjusted from 122 to 124, and the width between adjacent apertures along each column is adjusted from w22 to w24. For example, length 124 is adjusted from 130 nm up to 145 nm, and width w14 is adjusted from 130 nm up to 170 nm. In various implementations, the pitch adjustment is effected by choosing or manufacturing a different mask or by adjusting the location of apertures in a given mask to match the desired pitch. As indicated in FIG. 2B, the aperture size (i.e., w20) does not vary. In some implementations, different aperture sizes are selected, in addition to varying the pitch size. Also, the mask is positioned such that a respective corner of each aperture is aligned with a respective (desired) position (on the resist layer 102) of a respective sub-lithographic device component. For example, as indicated, aperture indicated by A21 is positioned such that a corner of the aperture aligns with a desired position of a sub-lithographic device component (indicated by device component dc211 in FIG. 2C). In some implementations, each aperture position (characterized by its corners) aligns with desired positions of a respective plurality of device components. For example, position of aperture indicated by A21 aligns with desired positions of components dc211, dc212, and dc213 (described below in reference to FIGS. 2C-2E). Following the placement of the mask of resist layer 102, the resist layer 102 is partially exposed to a radiant energy via apertures indicated by A21, A22, . . . , A29 in FIG. 2B. As a result, regions on the resist layer 102 that correspond to the apertures are partially exposed.

In FIG. 2C, the mask position is adjusted such that position of each aperture is changed from a first position to a second position. For example, the position of the aperture indicated by A21 is adjusted to a position indicated by B21, the position of the aperture indicated by A22 is adjusted to a position indicated by B22, and so on. In various implementations, this adjustment is effected by moving the mask along a first axis (e.g., after calculating a desired distance along the first axis) and, subsequently, along a second axis substantially perpendicular to the first axis. The mask position is adjusted such that a respective corner of each aperture (e.g., a corner opposite to the one described above in reference to FIG. 2B) is aligned with the respective (desired) position (on the resist layer 102) of the respective sub-lithographic device component. For example, as indicated, aperture indicated by B21 is positioned such that a corner of the aperture aligns with a desired position of the sub-lithographic device component (indicated by position for device component dc211 in FIG. 2C). The resist layer 102 is partially exposed (for a second time) to a radiant energy via apertures indicated by B21, B22, . . . , B29 in FIG. 2C. As a result, regions on the resist layer 102 that correspond to the apertures are partially exposed. This second exposure results in full exposure in some regions of the resist layer 102. For example, in FIG. 2C, the region corresponding to the desired position of device component dc211 is fully exposed after the two exposures. In some implementations, a different mask with aperture positions, indicated by B21, B22, . . . , B29, is used, instead of adjusting the mask in FIG. 2B.

FIG. 2D further illustrates this process for fabricating a second device component (e.g., device components dc212, dc222, dc292) corresponding to each sub-lithographic device (described above in reference to FIG. 2C), according to some implementations. Similar to FIG. 2C, the mask position is adjusted such that the aperture indicated by B21 is shifted to C21, the aperture indicated by B22 is shifted to C22, and so on. Again, each aperture position is adjusted such that a respective corner (e.g., a different corner than the ones described above in reference to FIGS. 2B and 2C) is aligned with a desired position (or a corner) of a second respective device component on the resist layer 102. For example, in FIG. 2D, A21 and C21 align with opposite (desired) corners of device component dc212, A22 and C22 align with opposite (desired) corners of device component dc222, and so on.

FIG. 2E further illustrates this process for fabricating a third device component (e.g., device components dc213, dc223, dc293) corresponding to each sub-lithographic device (described above in reference to FIG. 2C), according to some implementations. Similar to FIG. 2D, the mask position is adjusted such that the aperture indicated by C21 is shifted to D21, the aperture indicated by C22 is shifted to D22, and so on. Again, each aperture position is adjusted such that a respective corner (e.g., a different corner than the ones described above in reference to FIGS. 2B, 2C, and 2D) is aligned with a desired position (or a corner) of a second respective device component on the resist layer 102. For example, in FIG. 2E, A21 and D21 align with opposite (desired) corners of device component dc213, A22 and D22 align with opposite (desired) corners of device component dc223, and so on.

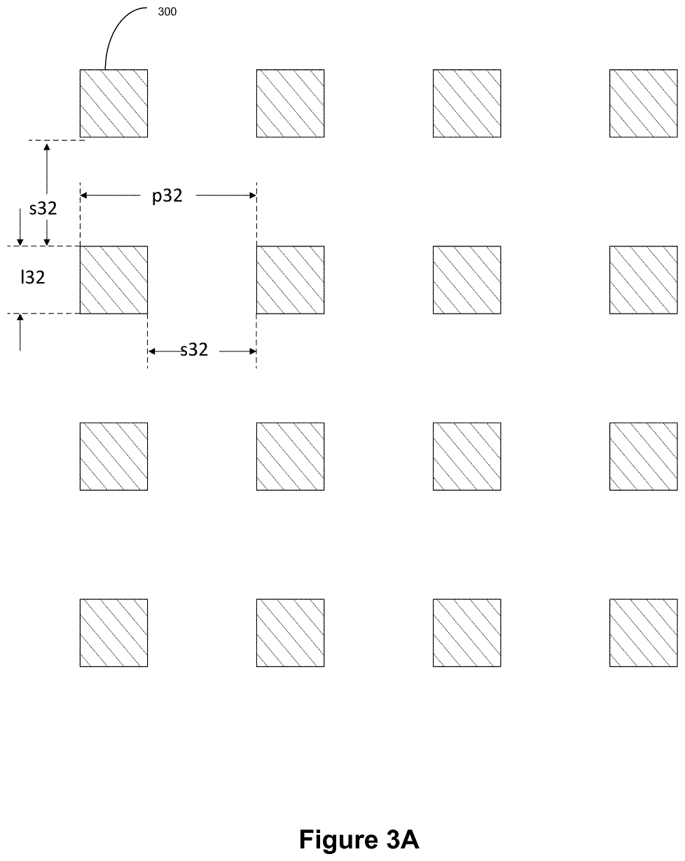

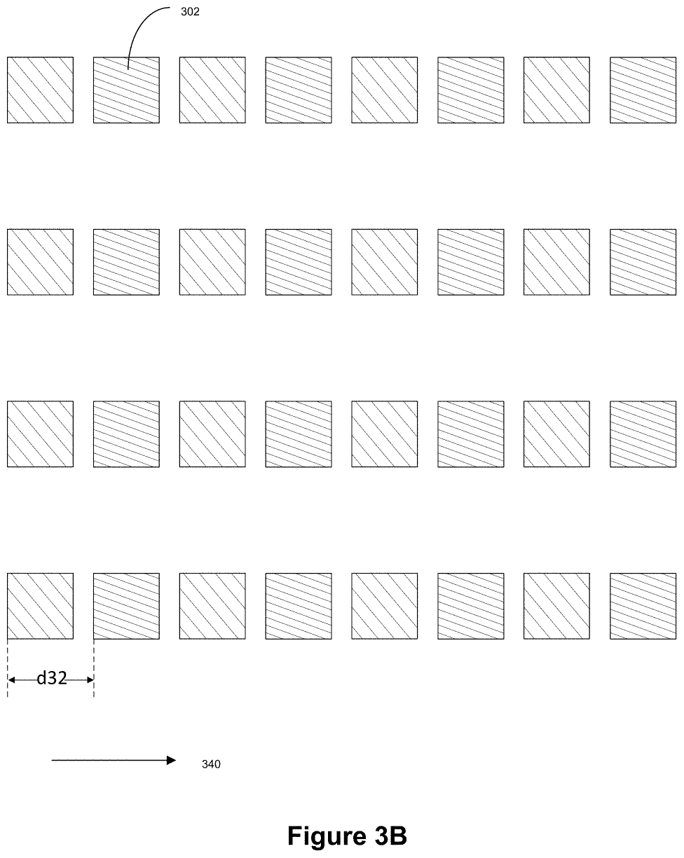

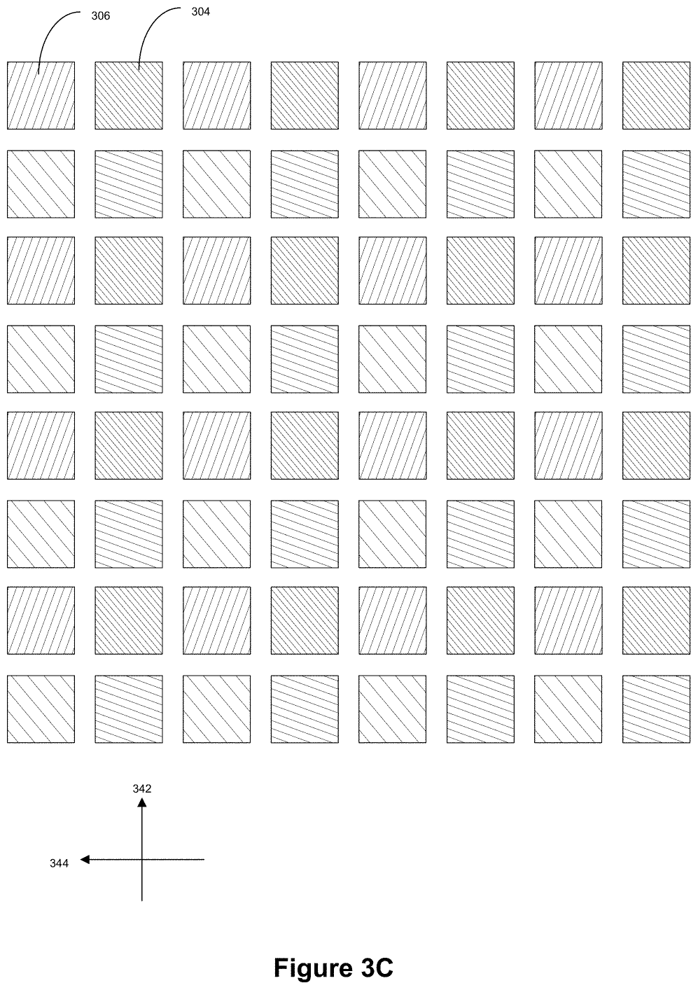

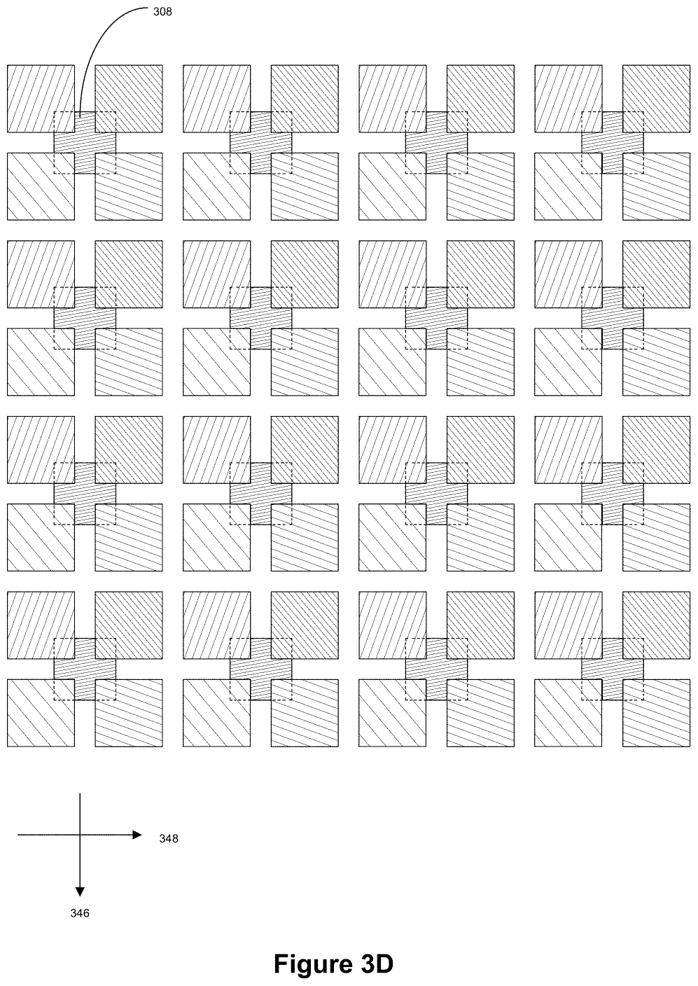

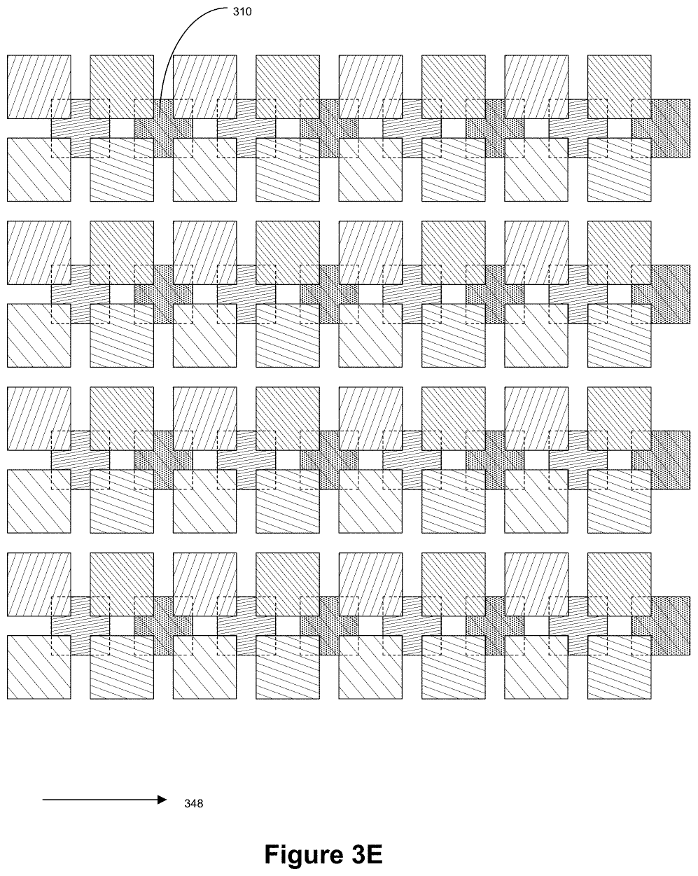

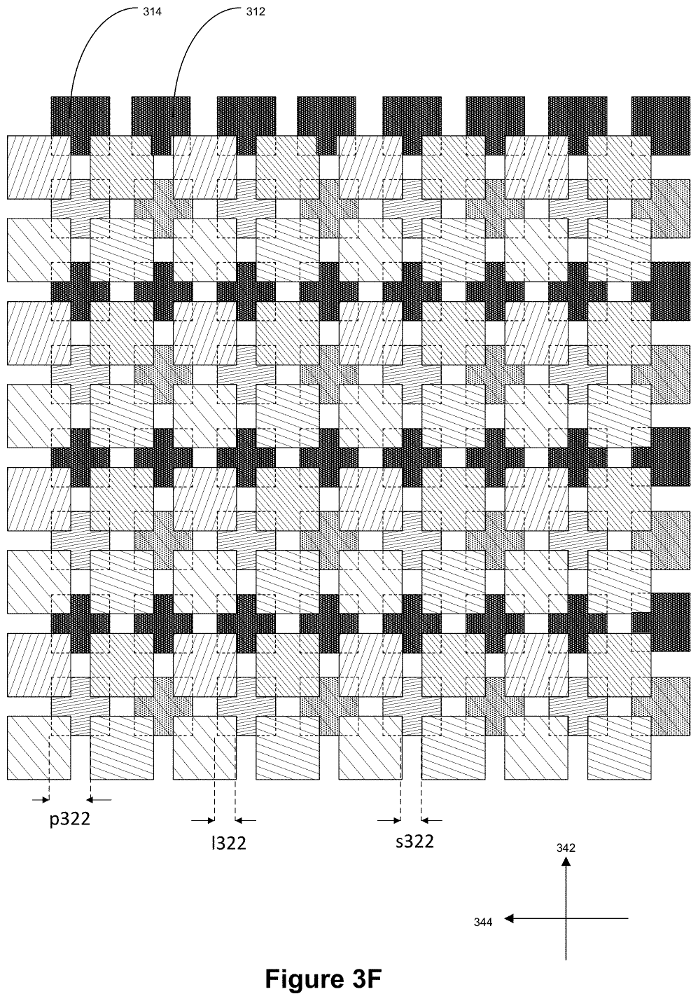

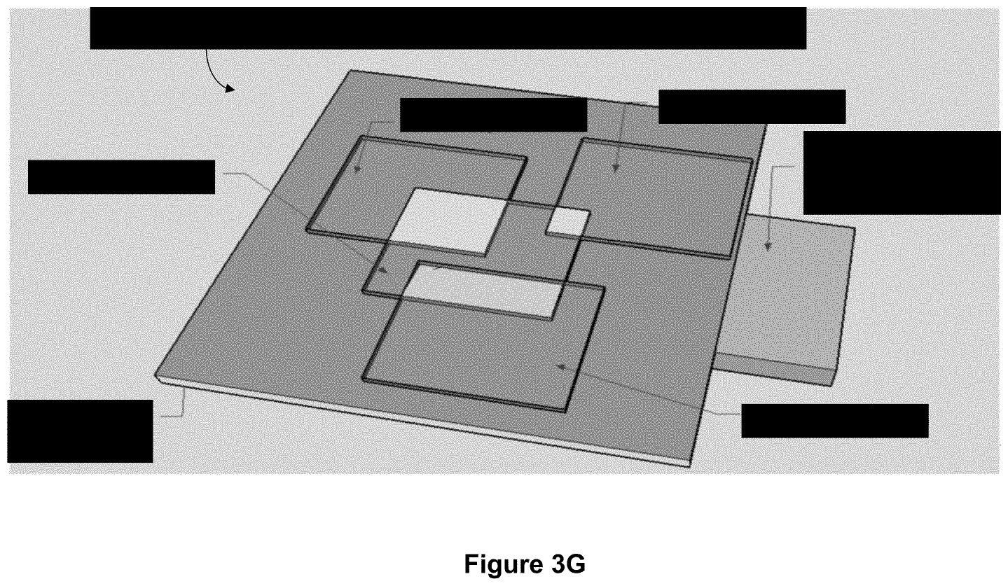

FIG. 3A shows a schematic diagram of a representative layout for fabricating devices in accordance with some implementations. Each of the shaded regions 300 represent apertures of a mask, according to some implementations. Each aperture is a square of length 132 (an expected line size if the apertures are fully exposed; e.g., 65 nm), according to some implementations. The space between the apertures 300 is indicated by s32 (e.g., 115 nm). Each aperture is at a distance p32 (sometimes called a pitch; e.g., 180 nm) from a neighboring aperture, according to some implementations. FIG. 3A corresponds to a first exposure through the apertures indicated by regions 300, according to some implementations.

FIGS. 3B-3F illustrate a representative process for fabrication that improves tool density in accordance with some implementations. FIG. 3B corresponds to a second exposure after moving the mask (indicated by regions 300 in FIG. 3A) by a distance d32 (e.g., 90 nm) along a first direction 340 (sometimes referred to as an X-axis or X-direction), thereby exposing regions 302 (corresponding to respective apertures), according to some implementations.

FIG. 3C corresponds to a third exposure after moving the mask (indicated by regions 302 in FIG. 3B) by the distance d32 (e.g., 90 nm) along a second direction 342 substantially perpendicular to the first direction 340 (sometimes referred to as a Y-axis or Y-direction), thereby exposing regions 304 (corresponding to respective aperture positions), according to some implementations. FIG. 3C also corresponds to a fourth exposure after moving the mask (indicated by regions 304) by the distance d32 (e.g., 90 nm) along a third direction 344 substantially perpendicular to the second direction 342 (e.g., parallel but opposite to direction 340), thereby exposing regions 306 (corresponding to respective aperture positions), according to some implementations. After the third and fourth exposure, density of devices that can be fabricated in the exposed regions (sometimes called tool density) is increased by 2.5 times relative to FIG. 3A, according to some implementations.

FIG. 3D corresponds to a fifth exposure after moving the mask (indicated by regions 306 in FIG. 3C) by half of the distance d32 (e.g., 45 nm) along a fourth direction 346 (substantially perpendicular to direction 344) followed by moving the mask by half of the distance d32 along a fifth direction 348 (substantially perpendicular to direction 346), thereby exposing regions 308 (corresponding to respective apertures), according to some implementations.

FIG. 3E corresponds to a sixth exposure after moving the mask (indicated by regions 308 in FIG. 3D) by the distance d32 (e.g., 90 nm) along the fifth direction 348, thereby exposing regions 310 (corresponding to respective apertures), according to some implementations.

FIG. 3F corresponds to a seventh exposure after moving the mask (indicated by regions 310 in FIG. 3E) by the distance d32 (e.g., 90 nm) along the second direction 342, thereby exposing regions 312 (corresponding to respective aperture positions), according to some implementations. FIG. 3F also corresponds to an eighth exposure after moving the mask (indicated by regions 312) by the distance d32 (e.g., 90 nm) along the third direction 344, thereby exposing regions 314 (corresponding to respective aperture positions), according to some implementations.

As illustrated in FIG. 3F, the smallest squares are of length 1322 (an expected line size or pillar size when the apertures are double partially exposed; e.g., 20 nm), according to some implementations. The space between the double partially exposed squares is indicated by s322 (e.g., 25 nm). Each double partially exposed square is at a distance p322 (a new pitch; e.g., 45 nm) from a neighboring double partially exposed square, according to some implementations. As illustrated, after the eighth exposure, density of tools that can be fabricated in the exposed regions is increased even more relative to FIG. 3C, according to some implementations.

To illustrate tool density improvement, suppose tool feature capability (a limitation in the lithographic process) is 130 nm by 130 nm. In some implementations, new feature area (as a result of the techniques described herein) is 45 nm by 45 nm. This provides a density of improvement of (130/45)\hat{ }2 (i.e., approximately 8.34 times improvement). As another example, suppose the starting layout feature (sometimes called tool feature are capability) is 180 nm by 180 nm. In some implementations, by applying the techniques described herein, the new feature are can be improved to 45 nm by 45 nm, providing a density improvement of (180/45)\hat{ }2 (i.e., 16 times improvement).

FIG. 3G illustrates a schematic diagram of a representative process 300 for fabricating sub-lithographic devices via multiple partial exposures in accordance with some implementations. A dielectric layer 302 is shown on top of a metal line 304, according to some implementations. A resist layer (not shown) is deposited on top of the dielectric layer 302. After partially exposing the resist layer multiple times (indicated by exposures 310, 312, 314, and 316), regions on the resist layer subject to full exposures (as indicated by overlap of regions subject to partial exposures 310 and 312, overlap of regions subject to partial exposures 310 and 314, and overlap of regions subject to partial exposures 310 and 316) are developed. The top dielectric 302 is then etched, according to some implementations.

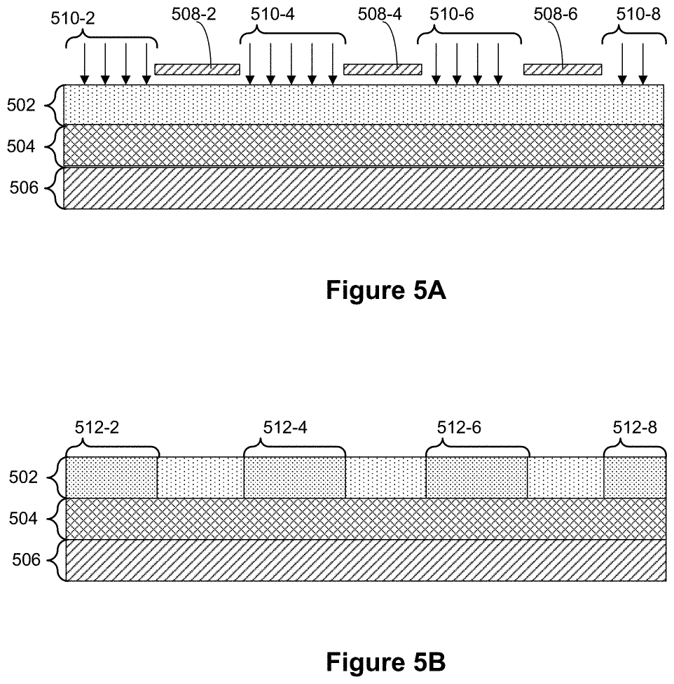

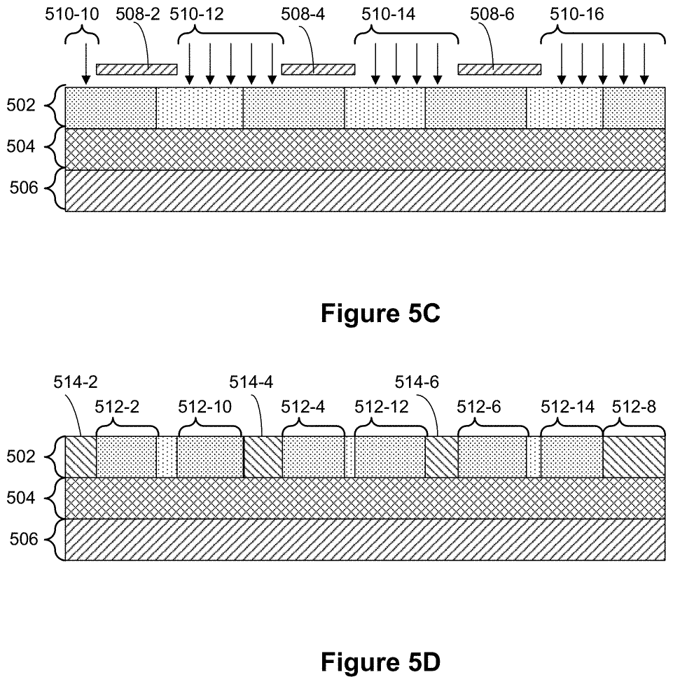

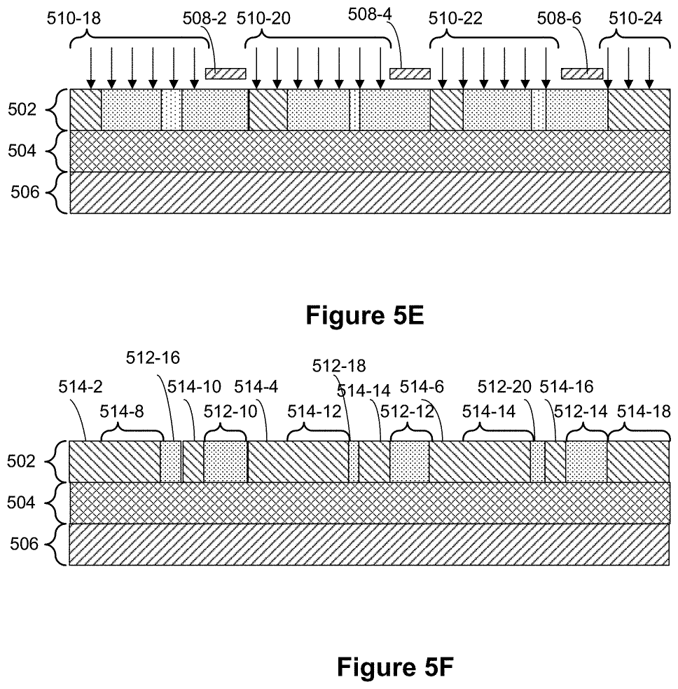

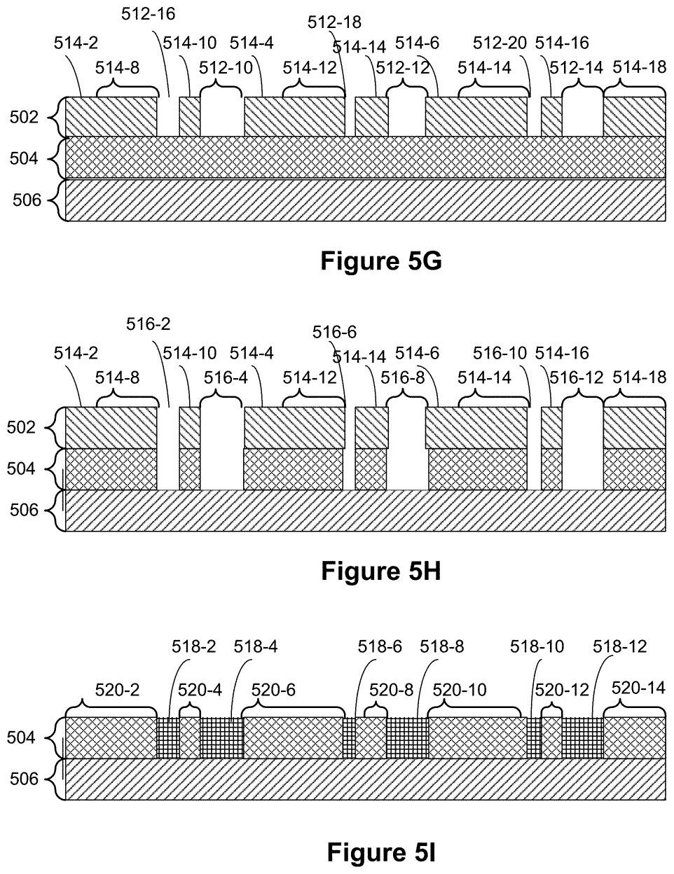

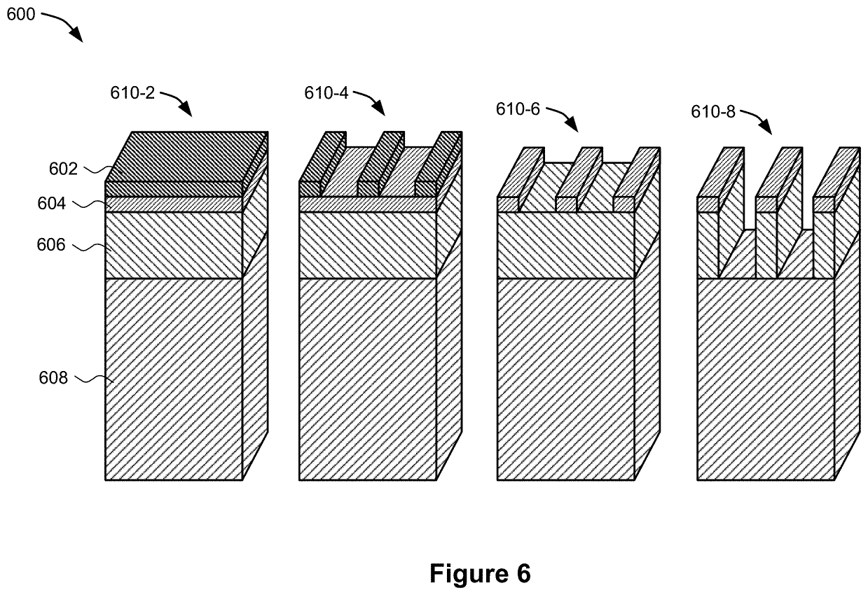

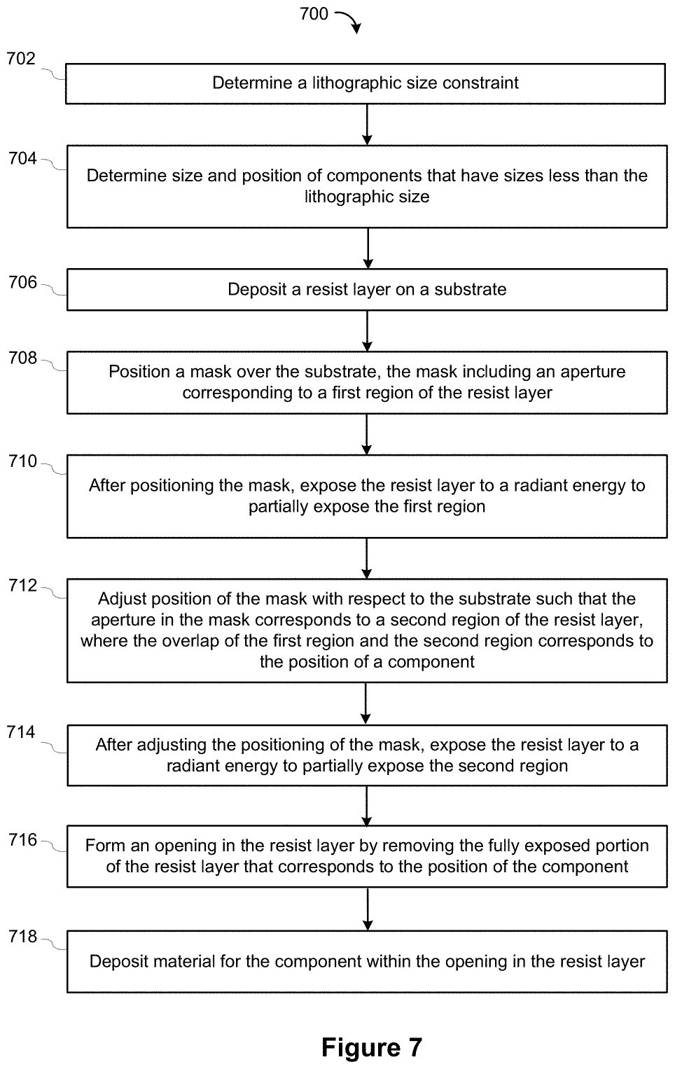

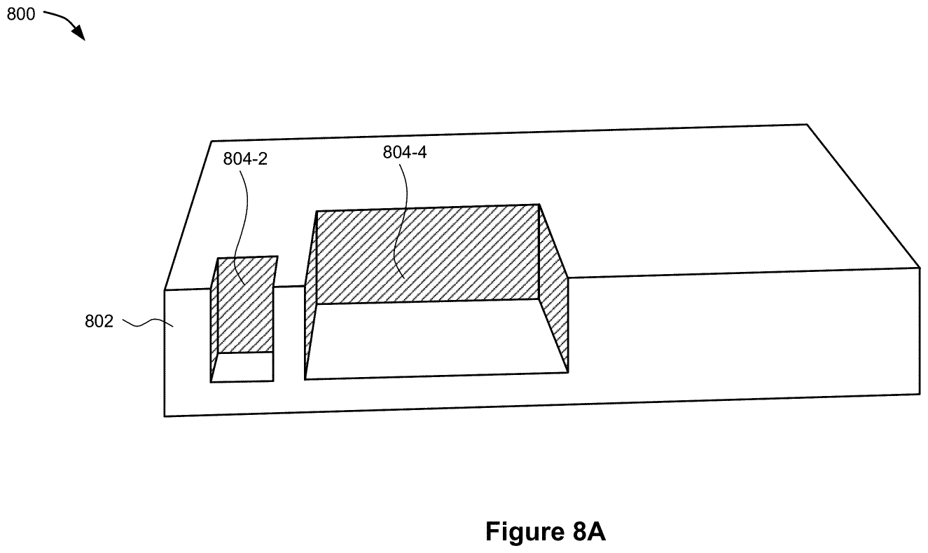

FIGS. 4A-4I illustrate a representative process for fabricating sub-lithographic devices in accordance with some implementations. FIGS. 4A, 4C, and 4E are corresponding cross-sectional views of the layouts in FIGS. 1B, 1C, and 1D, respectively. FIGS. 4A-4I are described below in reference to FIG. 7. FIGS. 5A-5I illustrate a representative process for fabricating sub-lithographic devices using a negative photoresist (in contrast to positive photoresist shown in FIGS. 4A-4I) in accordance with some implementations. FIGS. 5A-5I are described below after the description for FIG. 7. FIG. 6 illustrates a representative process for fabricating lithographic devices using a hard mask (protective) layer to prevent cavity formation in partial exposed regions of a resist layer in accordance with some implementations. FIG. 6 is also described below in reference to FIG. 7.

An Example Method for Fabricating Sub-Lithographic Devices

FIG. 7 illustrates a flowchart of a method 700 for fabricating sub-lithographic devices in accordance with some implementations. The method 700 comprises determining (702) a lithographic size constraint. For example, in FIG. 1B, 114 indicates a lithographic size constraint for a lithographic process. In some implementations, the step 702 includes identifying a predetermined lithographic size constraint of the lithographic process used in the fabrication.

The method 700 further comprises determining (704) size and position of components that have sizes less than the lithographic size. In some implementations, the step 704 includes determining a component size and positioning for a first component of a plurality of components of the sub-lithographic device, including determining that the component size is less than the lithographic size constraint. For example, FIG. 1C shows component dc11 corresponding to a first sub-lithographic device. For this example, the method 700 includes determining size and positioning for component dc11 of the first sub-lithographic device. The position includes a first corner (e.g., corner 112; FIG. 1C) and a second corner (e.g., corner 114; FIG. 1C) diagonally opposed to the first corner.

The method 700 further includes depositing (706) a resist layer (e.g., a positive photoresist) on a substrate (e.g., a planar substrate). For example, FIGS. 4A-4I show a resist layer 402 over a substrate layer 406. The resist layer has a sensitivity to a radiant energy, and a first exposure time. For example, FIG. 4A indicates the radiant energy by arrows 410-2, 410-4, and 410-6. The positioning for the first component corresponds to a first portion of the resist layer. In some implementations, the first exposure time is based on the composition and depth of the resist layer. In some implementations, the first exposure time is based on the sensitivity of the resist layer to the radiant energy. In some implementations, the first exposure time is based on the radiation wavelength used by an exposure tool used in the fabrication process. The first exposure time is sometimes called a first full exposure time or a full exposure time in reference to a time required to fully expose the resist layer to the radiant energy.

The method 700 further comprises positioning (708) a mask over the substrate, the mask including an aperture corresponding to first region of the resist layer. In some implementations, the step 708 includes positioning a first mask over the substrate, the first mask including a first aperture corresponding to a first region of the resist layer aligned with the first corner. The first region includes the first portion and has a size larger than the component size. For example, FIG. 1B shows a first mask (comprising the spaces between the apertures A1, A2, . . . , A9). FIG. 4A is a cross-sectional view of FIG. 1B at section X-X, according to some implementations. The cross-sectional view of the mask is indicated by 408-2, 408-4, 408-6, and 408-8. Spaces indicated by 410-2, 410-4 and 410-6 in FIG. 4A correspond to apertures A1, A2, and A3, respectively. A first aperture A1 corresponds to a first region of a resist layer 102. The aperture A1 corresponds to a first region of the resist layer 102 that is aligned with a first corner 112 of component dc11 shown in FIG. 1C. The first region (e.g., size of aperture A1) includes the first portion and has a size larger than the component size (e.g., size of component dell).

The method 700 also includes, after positioning the mask, exposing (710) the resist layer to a radiant energy to partially expose the first region. In some implementations, the step 710 includes, after positioning the first mask, exposing the resist layer to the radiant energy for a first time, less than the first exposure time, to partially expose the first region. In some implementations, the method further comprises selecting the first time to be at least half of the first exposure time. For example, exposure through A1 in FIG. 1B, indicated by the arrows 410 in cross-sectional view in FIG. 4A, results in partially exposed region 412-2 in FIG. 4B. In other words, the region marked as A1 in FIG. 1B is partially exposed to the radiant energy for a first time.

The method 700 further comprises adjusting (712) position of the mask with respect to the substrate such that the aperture in the mask corresponds to a second region of the resist layer, where the overlap of the first region and the second region corresponds to the position of a component. In some implementations, the step 712 includes adjusting positioning of the first mask with respect to the substrate such that the first aperture in the first mask corresponds to a second region of the resist layer aligned with the second corner, the second region partially overlapping the first region. The overlap of the first region and the second region is the first portion of the resist layer. For example, as shown in FIG. 1C, the mask is adjusted such that the first aperture (position indicated by A1 in FIG. 1B) corresponds to a second region indicated by region B1 of the resist layer 102. Region B1 is aligned with the second corner 114 of the device component dc11. Also, as shown, the second region B1 partially overlaps the first region A1, and the overlap corresponds to the first portion of the resist layer that coincides with the position of the component indicated by dc11.

In some implementations, adjusting positioning of the first mask comprises one or more of: stepping the first mask along a first axis, and stepping the first mask along a second axis. For example, for the transition from FIG. 1B to FIG. 1C, the mask identified by the apertures A1, A2, . . . , A9 is stepping along a first axis substantially parallel to section X-X and stepped along a second axis substantially perpendicular to section X-X.

The method 700 further includes, after adjusting the positioning of the first mask, exposing (714) the resist layer to a radiant energy to partially expose the second region. In some implementations, the step 714 includes, after adjusting the positioning of the first mask, exposing the resist layer to the radiant energy for a second time, less than the first exposure time. The sum of the first time and the second time is equal to, or greater than, the first exposure time such that, after exposing for the first time and the second time, the first portion of the resist layer is fully exposed to the radiant energy. FIGS. 4C and 4D correspond to cross-sectional views of FIG. 1C at section X-X. Exposure through apertures (B1, B2, and B3) in FIG. 1C, indicated by the arrows 410-8, 410-10, and 410-12, respectively, in cross-sectional view in FIG. 4C, results in partially exposed regions 412-8, 412-10, and 412-12, respectively, as shown in FIG. 4D. The exposure through apertures (B1, B2, and B3) in FIG. 1C, also results in fully exposed regions 414-2, 414-4, and 414-6, respectively, because these regions were exposed for a first time as shown in FIG. 4A and for the second time now as shown in FIG. 4C.

FIGS. 4E and 4F correspond to cross-sectional views of FIG. 1D at section X-X, and correspond to causing full exposure for components dc12, dc22, and dc32, according to some implementations. In some implementations, after positioning the first mask as shown in FIG. 4E, exposing the resist layer to the radiant energy (indicated by arrows 410-14, 410-16, and 410-18), less than the first exposure time, to partially expose the resist layer. Exposure indicated by the arrow 410-14 in cross-sectional view in FIG. 4E, results in fully exposed region 414-8 in FIG. 4F, according to some implementations. Similarly, exposure indicated by the arrow 410-16 in cross-sectional view in FIG. 4E, results in fully exposed region 414-10 in FIG. 4F, and exposure indicated by the arrow 410-18 in cross-sectional view in FIG. 4E, results in fully exposed region 414-12 in FIG. 4F, according to some implementations.

The method 700 further includes forming (716) an opening in the resist layer by removing the fully exposed portion of the resist layer that corresponds to the position of the component, and depositing (718) material for the component within the opening in the resist layer. In some implementations, the step 716 includes forming an opening in the resist layer by removing the fully exposed first portion of the resist layer, and the step 718 includes depositing material for the first component within the opening in the resist layer. In some implementations, removing the fully exposed resist region is performed by using a developer solution. FIG. 4G shows an example of formation of an opening in the resist layer 402 (e.g., corresponding to the resist layer 102 shown in FIGS. 1A-1D) by removing the fully exposed portions of the resist layer (e.g., portions 414-2, 414-8, 414-4, 414-10, 414-6, and 414-12). The first portion of the resist layer is indicated by the opening corresponding to 414-2. FIG. 4I shows depositing material for one or more components deposited in the openings shown in FIG. 4G or FIG. 4H. In particular, material for the first component is deposited into the opening indicated by 414-2 in FIG. 4G as indicated by 416-2.

In some implementations, the method 700 further includes identifying a minimum pitch based on the lithographic size constraint, determining a second pitch, greater than the minimum pitch, based on the component size and positioning of each of the plurality of components. The second pitch is selected to prevent undesirable overlap when adjusting the positioning of the first mask, and generating the first mask based on the second pitch. For example, as described above with reference to FIG. 2A, 122 corresponds to a minimum pitch based on a size constraint of the lithographic process, and, in FIG. 2B, 124 corresponds to a second pitch that is greater than 122. The second pitch 124 is selected so as to prevent undesirable overlap when adjusting positioning of the mask. For example, 124 is chosen such that, in FIG. 2E, re-positioning of the mask as indicated by subsequent positions of aperture indicated by D21 (from C21 in FIG. 2D) avoids an overlap with B22 corresponding to a partial exposure for a second component (dc221, in particular; FIG. 2C).

In some implementations, the method 700 further comprises producing the first mask for fabrication of a plurality of sub-lithographic devices, including the sub-lithographic device. The method 700 further comprises associating the first aperture (e.g., region indicated as A1 in FIG. 1B) in the first mask to the sub-lithographic device. The method 700 also includes associating a second aperture (e.g., region indicated as A2 in FIG. 1B) in the first mask to a second sub-lithographic device, distinct from the sub-lithographic device. The method 700 further includes determining a first area of the resist layer (e.g., area A1 of resist layer 102) that will be at least partially exposed via the first aperture and adjustments to the first mask positioning (e.g., adjusting mask to expose A1 in FIG. 1B and B1 in FIG. 1C through a first aperture in the mask) during fabrication of the plurality of components. The method 700 also includes determining a second area of the resist layer (e.g., area A2 of resist layer 102) that will be at least partially exposed via the second aperture and the adjustments to the first mask (e.g., adjusting mask to expose A2 in FIG. 1B and B2 in FIG. 1C through a second aperture in the mask) during fabrication of a second plurality of components for the second sub-lithographic device. The method 700 also includes determining a pitch for the first mask based on a spacing between the plurality of sub-lithographic devices, the pitch sufficient to prevent overlap of the first area and the second area, and generating the first mask with the first aperture, the second aperture, and the determined pitch. For example, in FIG. 1B, pitch size 114 is selected such that region C1 (corresponding to a third exposure for a second component dc12 of the first sub-lithographic device) exposed in FIG. 1D does not overlap region B2 (corresponding to a second exposure for a first component dc21 of the second sub-lithographic device) exposed in FIG. 1C, according to some implementations.

In some implementations, the method 700 further comprises depositing a hard mask layer, such that cavities are not formed in partially exposed regions of the resist layer. FIG. 6 illustrates the process of using a hard mask layer to prevent cavities in undesirable regions of a resist layer, according to some implementations. A hard mask layer 604 (e.g., a silicon hard mask layer) is deposited (610-2) before a resist layer 602 (e.g., a thin photoresist) is deposited over a dielectric layer 606 (e.g., a SOC layer) that is deposited over a substrate 608. Subsequently, the process includes exposing and developing (610-4) the resist layer, followed by etching (610-6; e.g., using a fluorinated etching process) the hard mask layer 604, followed by etching (610-8; e.g., using a CO₂ or O₂ etching process) the dielectric layer 606, according to some implementations.

In some implementations, the method 700 further includes prior to depositing the resist layer, depositing a dielectric layer over the substrate. The method 700 also includes, after forming the opening in the resist layer, etching a corresponding opening in the dielectric layer, and removing the remaining resist layer. Depositing the material comprises depositing the material in the opening of the dielectric layer. FIG. 4A described above shows a dielectric layer 404 deposited over the substrate 406 prior to depositing the resist layer 402. FIG. 4H shows etching of corresponding openings in the dielectric layer 404 after formation of openings (e.g., openings 414-2, 414-8, 414-4, 414-10, 414-6, and 414-12) in the resist layer 402 in FIG. 4G, according to some implementations. FIG. 4I illustrates depositing the material for components in the openings of the dielectric layer 404, according to some implementations.

In some implementations, the method 700 further comprises determining a component size and positioning for a second component of the plurality of components. The positioning for the second component corresponds to a second portion of the resist layer. The method 700 also includes removing the first mask and positioning a second mask over the substrate, the second mask including a third aperture corresponding to a third region of the resist layer, the third region including the second portion and having a size larger than the component size for the second component, and after positioning the second mask, exposing the resist layer to the radiant energy for a third time, less than the first exposure time, to partially expose the third region. For example, instead of adjusting the position of a first mask for the transition from FIG. 1B to FIG. 1C, a second mask is used, the second mask including apertures corresponding to the regions B1, B2, B3, . . . , B9.

Fabrication of Sub-Lithographic Devices Using a Negative Photoresist

Referring now back to FIGS. 5A-5I, the figures illustrate a representative process for fabricating sub-lithographic devices using a negative photoresist (in contrast to a process using a positive photoresist shown in FIGS. 4A-4I) in accordance with some implementations. FIGS. 5A-5I are again explained in reference to flowchart shown in FIG. 7. The method 700 further includes depositing (706) a resist layer on a substrate (e.g., a planar substrate). For example, FIGS. 5A-5I show a resist layer 502 (a negative photoresist) over a substrate layer 506. The resist layer has a sensitivity to a radiant energy, and a first exposure time. For example, FIG. 5A indicates the radiant energy by arrows 510-2, 510-4, and 510-6. The positioning for the first component corresponds to a first portion of the resist layer.

The method 700 further comprises positioning (708) a mask over the substrate, the mask including an aperture corresponding to first region of the resist layer. In some implementations, the step 708 includes positioning a first mask over the substrate, the first mask including a first aperture corresponding to a first region of the resist layer aligned with the first corner. The first region includes the first portion and has a size larger than the component size. The cross-sectional view of the mask is indicated by 508-2, 508-4, and 508-6. Spaces indicated by 510-2, 510-4, and 510-6 in FIG. 5A correspond to apertures of the mask. A first aperture corresponds to a first region of a resist layer 102.

The method 700 also includes, after positioning the mask, exposing (710) the resist layer to a radiant energy to partially expose the first region. In some implementations, the step 710 includes, after positioning the first mask, exposing the resist layer to the radiant energy for a first time, less than the first exposure time, to partially expose the first region. In some implementations, the method further comprises selecting the first time to be at least half of the first exposure time. For example, exposure indicated by the arrows 510 in cross-sectional view in FIG. 5A results in partially exposed region 512-2 in FIG. 5B.

The method 700 further comprises adjusting (712) position of the mask with respect to the substrate such that the aperture in the mask corresponds to a second region of the resist layer, where the overlap of the first region and the second region corresponds to the position of a component. In some implementations, the step 712 includes adjusting positioning of the first mask with respect to the substrate such that the first aperture in the first mask corresponds to a second region of the resist layer aligned with the second corner, the second region partially overlapping the first region. The overlap of the first region and the second region is the first portion of the resist layer. In some implementations, adjusting positioning of the first mask comprises one or more of: stepping the first mask along a first axis, and stepping the first mask along a second axis.

The method 700 further includes, after adjusting the positioning of the first mask, exposing (714) the resist layer to a radiant energy to partially expose the second region. In some implementations, the step 714 includes, after adjusting the positioning of the first mask, exposing the resist layer to the radiant energy for a second time, less than the first exposure time. The sum of the first time and the second time is equal to, or greater than, the first exposure time such that, after exposing for the first time and the second time, the first portion of the resist layer is fully exposed to the radiant energy. FIGS. 5C and 5D correspond to cross-sectional views. Exposure through apertures indicated by the arrows 510-10, 510-12, 510-14, and 510-16, respectively, in cross-sectional view in FIG. 5C, results in fully exposed regions 514-2, 514-4, 514-6, and 512-8, respectively, as shown in FIG. 5D. Exposure through apertures indicated by the arrows 510-12, 510-14, and 510-16, respectively, in cross-sectional view in FIG. 5C, also results in partially exposed regions 512-10, 512-12, and 512-14, respectively, as shown in FIG. 5D.

FIGS. 5E and 5F correspond to cross-sectional views, according to some implementations. In some implementations, after positioning the first mask as shown in FIG. 5E, exposing the resist layer to the radiant energy (indicated by arrows 510-18, 510-20, 510-22, and 510-24), less than the first exposure time, to partially expose the resist layer. Exposure indicated by the arrow 510-18 in cross-sectional view in FIG. 5E, results in fully exposed regions 514-8 and 514-10 in FIG. 5F, according to some implementations. Similarly, exposure indicated by the arrow 510-20 in cross-sectional view in FIG. 5E, results in fully exposed regions 514-12 and 514-14 in FIG. 5F, and exposure indicated by the arrow 510-22 in cross-sectional view in FIG. 5E, results in fully exposed regions 514-14 and 514-16 in FIG. 5F, according to some implementations.

The method 700 further includes forming (716) an opening in the resist layer by removing the unexposed or partially exposed portion of the resist layer that corresponds to the position of the component, and depositing (718) material for the component within the opening in the resist layer. In some implementations, the step 716 includes forming an opening in the resist layer by removing the fully exposed first portion of the resist layer, and the step 718 includes depositing material for the first component within the opening in the resist layer. In some implementations, removing the unexposed or partially exposed resist region is performed by using a developer solution. FIG. 5G shows an example of formation of an opening in the resist layer 502 by removing the unexposed or partially exposed portions of the resist layer (e.g., portions 512-16, 512-10, 512-18, 512-12, 512-20, and 512-14). The first portion of the resist layer is indicated by the opening corresponding to 518-2. Figure SI shows depositing material for one or more components deposited in the openings shown in FIG. 5G or FIG. 5H. In particular, material for the first component is deposited into the opening indicated by 518-2 in FIG. 5I.

In some implementations, the method 700 further includes prior to depositing the resist layer, depositing a dielectric layer over the substrate. The method 700 also includes, after forming the opening in the resist layer, etching a corresponding opening in the dielectric layer, and removing the remaining resist layer. Depositing the material comprises depositing the material in the opening of the dielectric layer. FIG. 5A described above shows a dielectric layer 504 deposited over the substrate 506 prior to depositing the resist layer 502. FIG. 5H shows etching of corresponding openings in the dielectric layer 504 after formation of openings (e.g., openings 516-2, 516-4, 516-6, 516-10, and 516-12) in the resist layer 502 in FIG. 5G, according to some implementations. FIG. 5I illustrates depositing the material for components in the openings of the dielectric layer 504, according to some implementations.

Fabrication of Sub-Lithographic Phase Change Devices

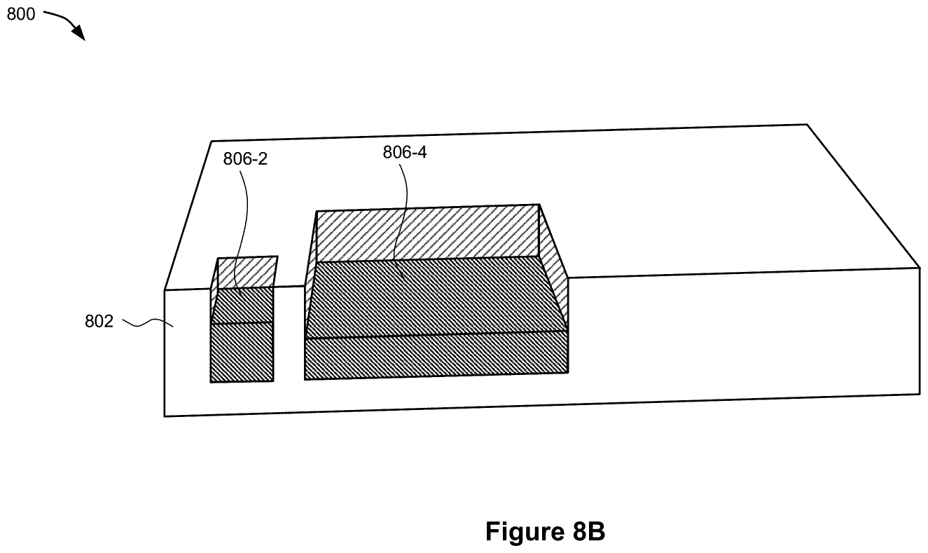

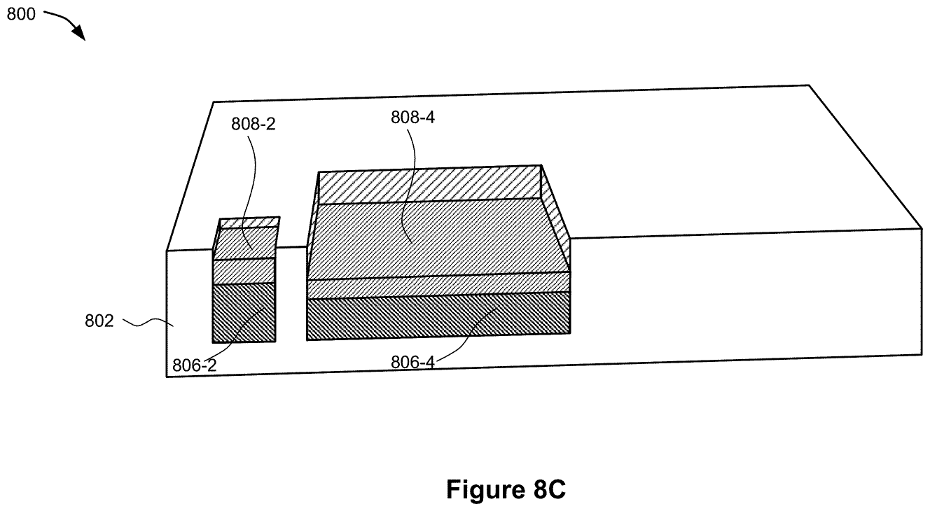

FIGS. 8A-8C illustrate a representative process 800 for fabricating a sub-lithographic phase change device in accordance with some implementations. Some devices, such as phase change devices, need sub-lithographic heater elements. For example, sub-lithographic openings are needed for filling in smaller volume of phase change material for reduced power requirements. The process 800 has a variety of applications. For example, the method can be used to fabricate a hybrid phase change and MPRAM multistate cell using one or more sub-lithographic features.

FIGS. 8A-8C illustrate fabricating two neighboring phase change components, each consisting of heater elements of different sizes, and phase change materials of different volumes, according to some implementations. The process 800 includes starting obtaining a substrate (not shown) and depositing a dielectric layer 802 over the substrate. Two openings 804-2 and 804-4 are etched in the dielectric layer 802. The two openings 804-2 and 804-4 are intended for two different sized elements. FIG. 8B illustrates deposition of heater materials 806-2 and 806-4 in the openings 804-2 and 804-4, respectively, according to some implementations. In some implementations, the step includes etching back of the openings 804-2 and 804-4. The different heater elements are of different thicknesses (because the volume of deposition is constant for the different openings). In particular, the opening 804-2 has a thicker heater element compared to the opening 804-4. FIG. 8C illustrates deposition (e.g., physical vapor deposition) of phase change materials 808-2 and 808-4 in the respective openings 804-2 and 804-4 over the heater elements 806-2 and 806-4, respectively, according to some implementations. Similar to the underlying heater elements, the thicknesses of the phase change materials 808-2 and 808-4 are different, although the volume of the phase change material deposited is similar. In some implementations, the openings are etched after the deposition of the phase change materials. In some implementations, the openings are filled (not shown) with the phase changed material (e.g., filled to the top of the dielectric slap 802), and subsequently polished (not shown; e.g., chemical or mechanical polishing of the phase change material). In some implementations, fabricated devices include higher volume phase change element with a slower heater. In some implementations, fabricated devices include lower volume phase change element with a bigger heater. In some implementations, the techniques described herein can be used to quadruple density of MRAM pillars (e.g., to manufacture 25 nm size pillars with 15 nm gap).

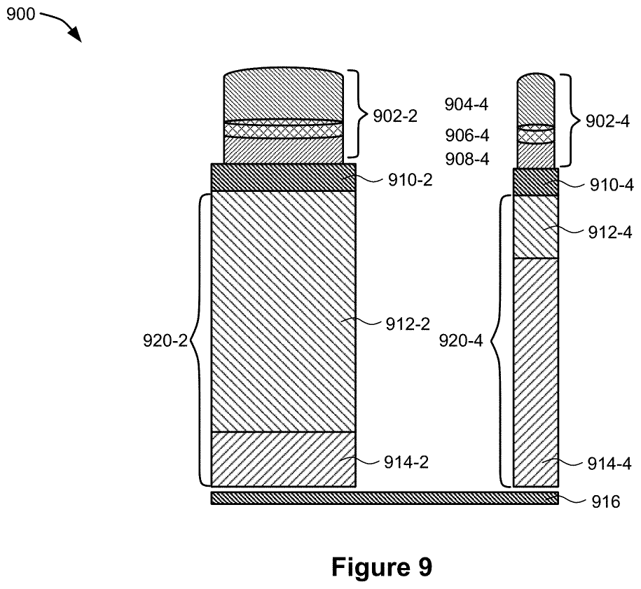

FIG. 9 illustrates a representative sub-lithographic phase change device 900 in accordance with some implementations. The phase change device comprises a bottom electrode 916, a plurality of phase change components (e.g., the components 920-2 and 920-4), a plurality of top electrodes (e.g., the electrodes 910-2 and 910-4), each top electrode coupled to a respective phase change component (e.g., the top electrode 910-2 coupled to the component 920-2, and the top electrode 910-4 coupled to the component 920-4), and a plurality of Magnetic Tunnel Junction (MTJ) devices (e.g., devices 902-2 and 902-4) electrically-coupled to the phase change components via the plurality of top electrodes. In some implementations, each MTJ device is coupled to a respective top electrode.

In some implementations, the plurality of phase change components includes a first phase change component (e.g., the component 920-2) and a second phase change component (e.g., the component 920-4). The first phase change component is larger than the second phase change component.

In some implementations, each phase change component is composed of a second material (e.g., the material 912) layered on a first material (e.g., the material 914). In some implementations, the plurality of phase change components includes a first phase change component and a second phase change component, and the first phase change component has a different ratio of the first material to the second material than the second phase change component. For example, in FIG. 9, the first phase change component 920-2 has a different ratio of the first material 914-2 to the second material 912-2 compared to the second phase change component 920-4, according to some implementations.

In some implementations, the first material is a phase change material, and the second material is a material corresponding to a heater element. In some implementations, the phase change material is a material corresponding to a phase change resistor. In some implementations, power consumed by the phase change component during operation is based on the volume of the phase change material.

An Example Method for Fabricating Sub-Lithographic Phase Change Devices

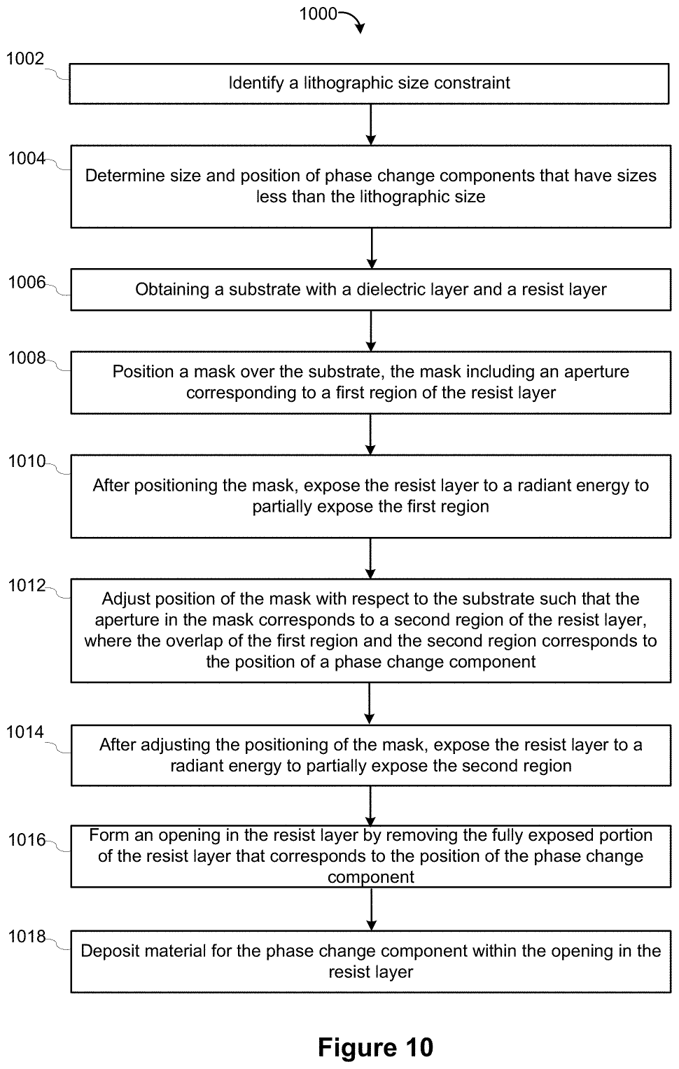

FIG. 10 illustrates a flowchart of a method 1000 for fabricating sub-lithographic phase change devices in accordance with some implementations. The method 1000 includes identifying (1002) a lithographic size constraint. The method 1000 also includes determining (1004) size and position of phase change components (e.g., the components 920-2 and 920-4; FIG. 9) that have sizes less than the lithographic size. The method 1000 further includes obtaining (1006) a substrate with a dielectric layer a resist layer stacked on top. The resist layer has a sensitivity to a radiant energy with a first exposure time. The method 1000 further includes positioning (1008) a mask over the substrate, the mask including an aperture corresponding to a first region of the resist layer. For example, FIGS. 1A-1D described above illustrate a process for positioning a mask over a substrate.

The method 10000 further includes partially exposing (1010) the first region of the resist layer to the radiant energy, less than the first exposure time, to partially expose the first region. The method 1000 further comprises adjusting (1012) position of the mask with respect to the substrate such that the aperture in the mask corresponds to a second region of the resist layer, where the overlap of the first region and the second region corresponds to the position of a phase change component. After adjusting the position of the mask, the method includes exposing (1014) the resist layer to a radiant energy to partially expose the second region for a time less than the first expose time. The method 10000 further includes forming (1016) an opening in the resist layer by removing the fully exposed portion of the resist layer that corresponds to the position of the phase change component, and depositing materials (e.g., the material 914-2 followed by the material 914-2) for the phase change component (e.g., the component 920-2 in FIG. 9) within the opening in the resist layer. In some implementations, the method 10000 includes repeating steps 1008 through 1018 and any related processes for obtaining a second phase change component (e.g., the component 920-4 in FIG. 9).

Fabrication of Devices with Reduced Isolation Regions

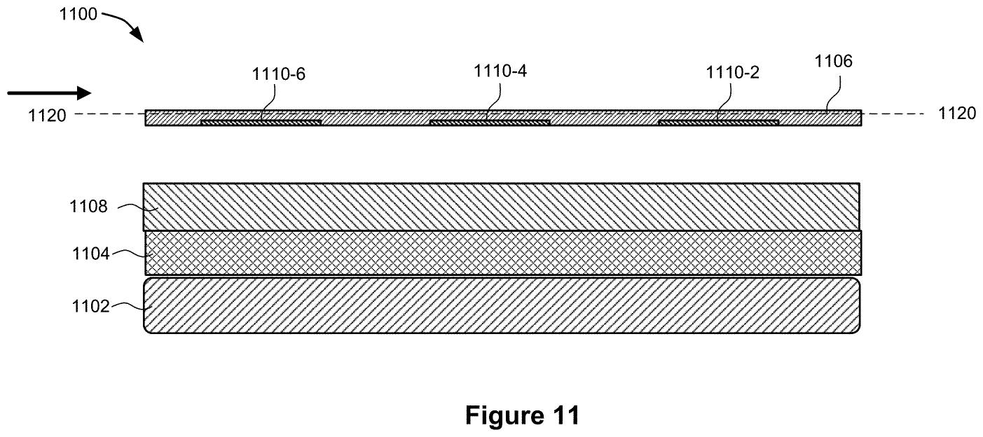

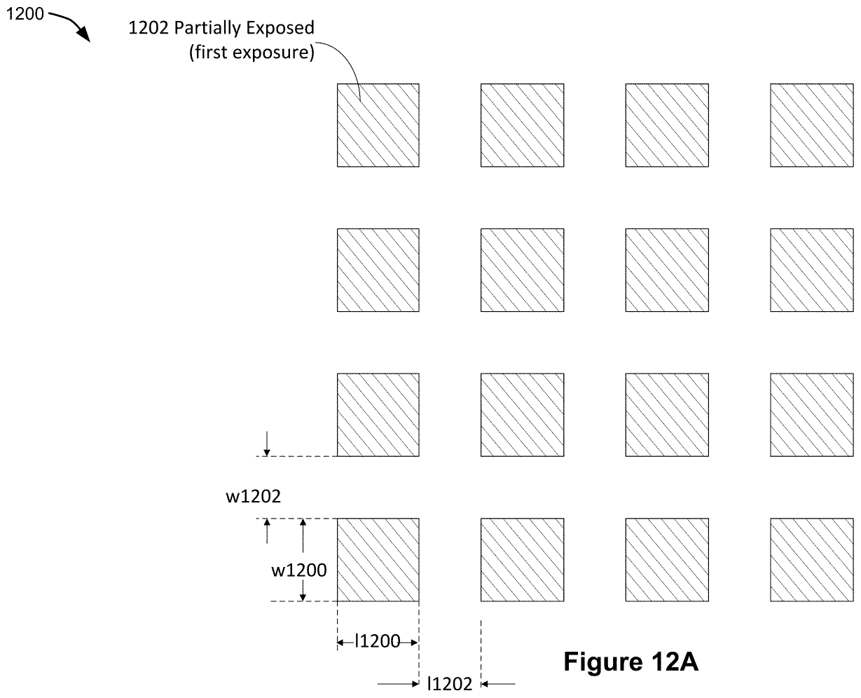

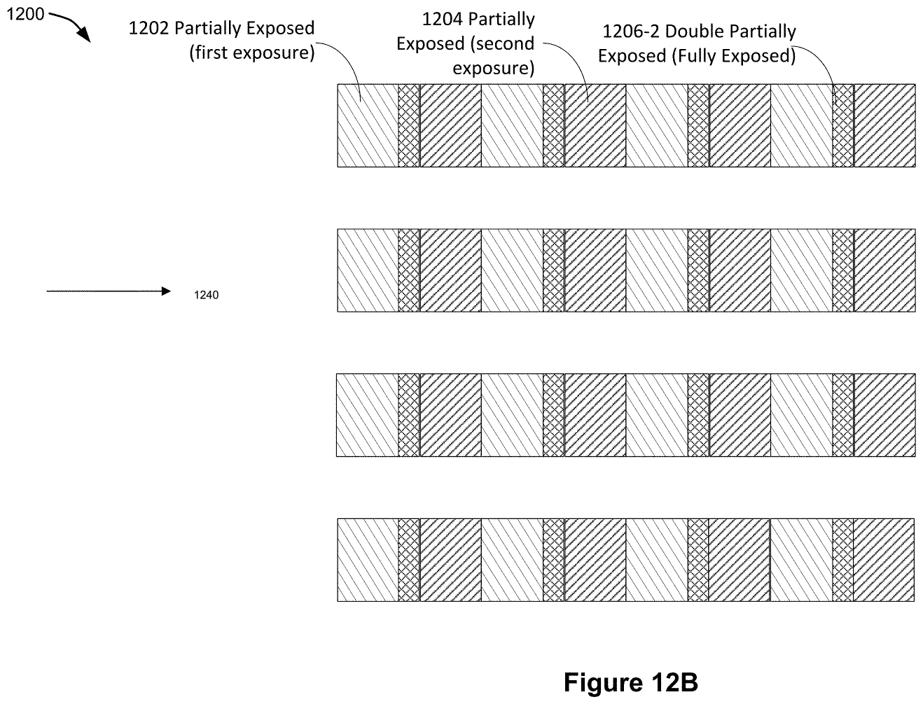

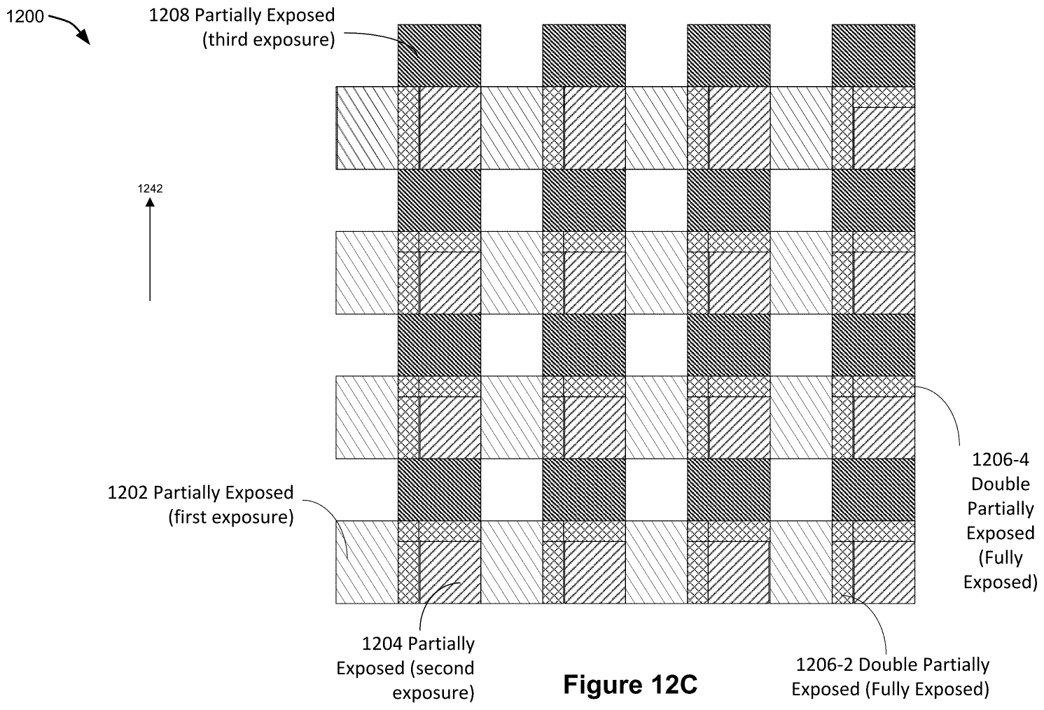

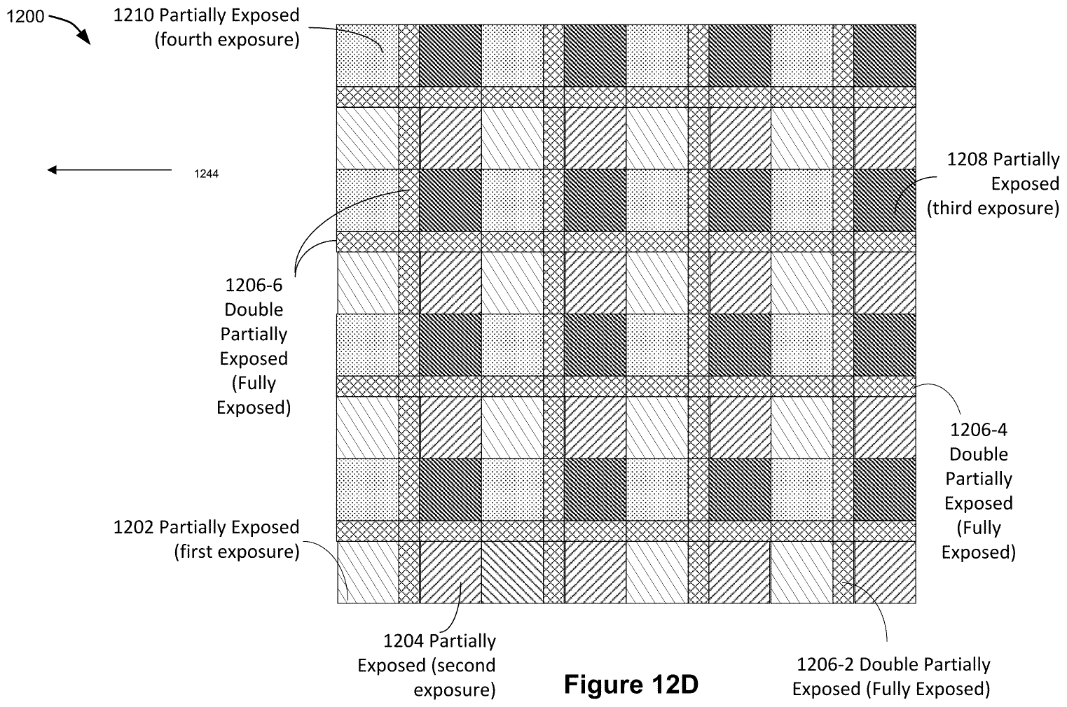

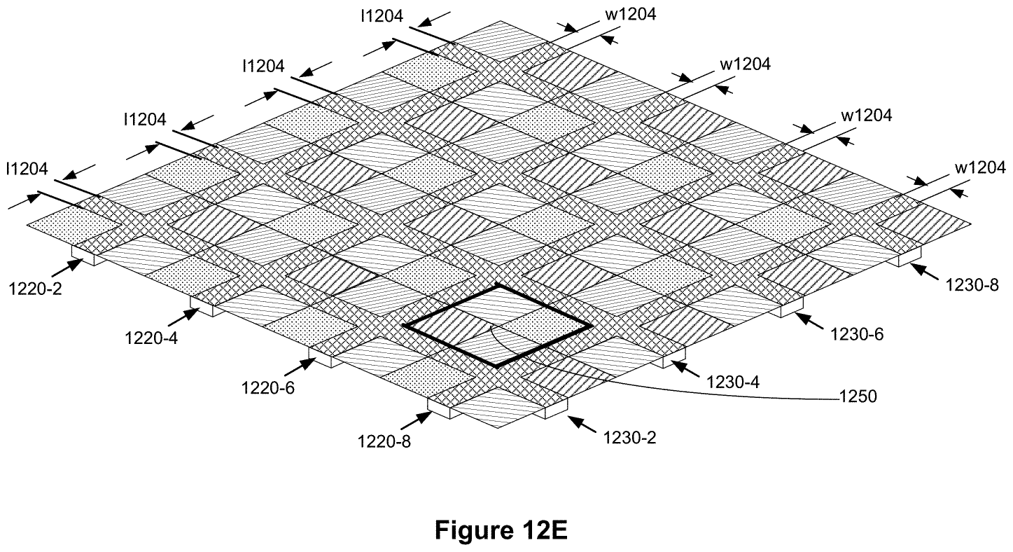

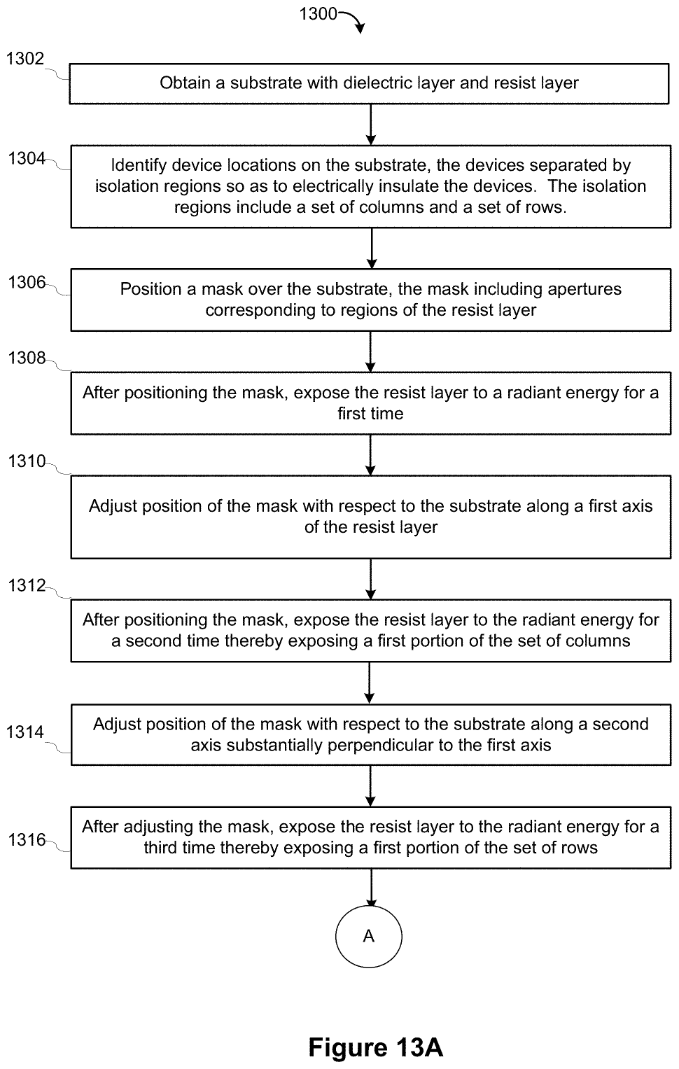

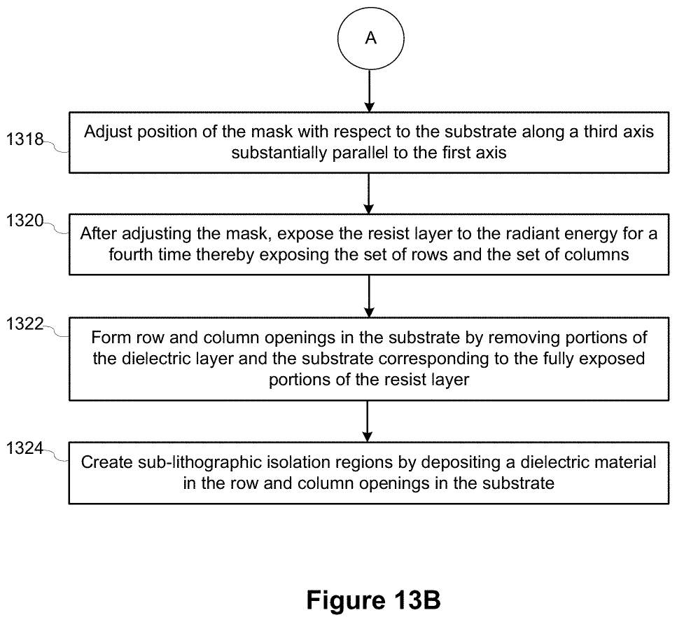

FIG. 11 illustrates a sectional view of a representative layout for fabricating devices with reduced isolation regions there between, in accordance with some implementations. FIGS. 12A-12E show schematic diagrams of a representative layout for fabricating devices with reduced isolation regions there between, in accordance with some implementations. FIGS. 11 and 12A-12E are described below in reference to FIGS. 13A and 13B.

FIGS. 13A and 13B illustrate a flowchart of a method 1300 for fabricating devices with reduced isolation regions there between in accordance with some implementations. In some implementations, the method 1300 reduces shallow trench isolation (STI) spacing (e.g., down from 65 nm on a reticle to 20 nm on a wafer). In some implementations, the method 1300 increases active width (e.g., up from 65 nm to 130 nm). In some implementations, the method 1300 can be used to manufacture MOS planar transistor devices.

The method 1300 includes obtaining (1302) a substrate (e.g., the substrate 1102, FIG. 11) with a dielectric layer (e.g., layer 1104) and a resist layer (e.g., the resist layer 1106) stacked thereupon. The resist layer 1108 has a sensitivity to a radiant energy. The resist layer 1108 has a first exposure time to the radiant energy. The method 1300 also includes identifying (1304) a plurality of device locations on the substrate. A plurality of isolation regions separates the plurality of device locations from one another such that the plurality of devices is electrically insulated from one another. The plurality of isolation regions includes a first set of rows and a first set of columns. The first set of columns is substantially perpendicular to the first set of rows. For example, in FIG. 12E, isolation regions include rows 1220-2, 1220-4, 1220-6, and 1220-8, and columns 1230-2, 1230-4, 1230-6, and 1230-8 that are substantially perpendicular to the rows, according to some implementations. The rows and columns isolate, and thereby insulate, adjacent regions (that correspond to device locations; indicated by rectilinear shapes in FIG. 12E).

A width or a dimension of each column is less than a lithographic size constraint, and a width or a dimension of each row is less than the lithographic size constraint. For example, the width w1204 in FIG. 12E is less than the width w1200 (e.g., 850 nm) of FIG. 12A, and the length l1204 in FIG. 12E is less than the length l1200 (e.g., 850 nm) of FIG. 12A. In FIG. 12A, the shaded regions 1202 correspond to aperture positions of a mask, and the apertures are separated by the spaces indicated by the length l1202 (e.g., 650 nm) and the width w1202 (e.g., 650 nm), according to some implementations. FIG. 12A corresponds to an initial layout with active areas (each of the shaded regions 1202) each having a dimension w1200 by 11200 (e.g., 850 nm by 850 nm), and isolation areas (sometimes called isolation regions; the space between adjacent shaded regions 1202) each having a dimension of w1200 by 11202 (e.g., 850 nm by 650 nm; or 11200 by w1202 along the other axis).

The method 1300 further comprises fabricating the plurality of isolation regions including by positioning (1306) a first mask (e.g., the mask 1106, FIG. 11A) over the substrate. The method further comprises, after positioning the first mask, exposing (1308) the resist layer to the radiant energy for a first time, less than the first exposure time, to partially expose the resist layer. In some implementations, the method 1300 further comprises selecting the first time to be at least half of the first exposure time. For example, in FIG. 11, the mask 1106 includes apertures between blocks indicated by 1110-2, 1110-4, and 1110-6. For this example, exposing the resist layer 1108 to a radiant energy (e.g., as explained above in reference to FIGS. 4A-4E) for a period less than half of a full exposure time results in parts of the resist layer 1108 partially exposed (e.g., the regions 1202 shown in FIG. 12A), according to some implementations.

The method 1300 further comprises adjusting (1310) positioning of the first mask with respect to the substrate along a first axis. For example, in FIG. 12B, the position of the first mask 1106 is adjusted (relative to the position shown in FIG. 12A) along the axis 1240 (also indicated by the direction 1120 in FIG. 11), according to some implementations. In some implementations, the first mask position is adjusted by a length (e.g., 650 nm) such that the adjusted positions of the apertures of the first mask do not overlap with corresponding adjacent apertures of the first mask, and such that the adjusted positions of the apertures of the first mask overlap with the initial positions (e.g., the positions indicated by 1202 in FIG. 12A) of the respective apertures of the first mask. The method 1300 further comprises, after adjusting the positioning of the first mask along the first axis, exposing (1312) the resist layer to the radiant energy for a second time, less than the first exposure time. The sum of the first time and the second time is equal to, or greater than, the first exposure time such that, after exposing for the first time and the second time, a first portion of the first set of columns of the resist layer is fully exposed to the radiant energy. For example, in FIG. 12B, exposing the resist layer 1108 to a radiant energy (e.g., as explained above in reference to FIGS. 4A-4E) for a period less than half of a full exposure time for a second time results in parts of the resist layer 1108 partially exposed (e.g., the regions 1204), and parts of the resist layer 1108 fully exposed (e.g., the regions 1206-2) because the corresponding regions were partially exposed two times, according to some implementations. The fully exposed regions 1206-2 constitute a first portion of the first set of columns (e.g., the columns 1230-2, 1230-4, 1230-6, and 1230-8 of FIG. 12E), according to some implementations.

The method 1300 further comprises adjusting (1314) positioning of the first mask with respect to the substrate along a second axis (e.g., the axis 1242 shown in FIG. 12C) that is substantially perpendicular to the first axis (e.g., the axis 1240 in FIG. 12B). In some implementations, the first mask position is adjusted by a length (e.g., 650 nm) such that the adjusted positions of the apertures of the first mask do not overlap with corresponding adjacent apertures (along the axis 1242) of the first mask, and such that the adjusted positions of the apertures of the first mask overlap with earlier positions (e.g., the positions indicated by 1204 in FIG. 12B) of the respective apertures of the first mask. The method further comprises, after adjusting the positioning of the first mask along the second axis, exposing (1316) the resist layer to the radiant energy for a third time, less than the first exposure time. The sum of the first time and the third time is equal to, or greater than, the first exposure time such that, after exposing for the first time and the third time, a first portion of the first set of rows of the resist layer is fully exposed to the radiant energy. For example, in FIG. 12C, exposing the resist layer 1108 to the radiant energy (e.g., as explained above in reference to FIGS. 4A-4E) for a period less than half of a full exposure time for a third time results in parts of the resist layer 1108 partially exposed (e.g., the regions 1208), and parts of the resist layer 1108 fully exposed (e.g., the regions 1206-4) because the corresponding regions were partially exposed two times, according to some implementations. The fully exposed regions 1206-4 constitute a first portion of the first set of rows (e.g., the rows 1220-2, 1220-4, 1220-6, and 1220-8 of FIG. 12E), according to some implementations.

Referring next to FIG. 13B, the method 1300 further comprises adjusting (1318) positioning of the first mask with respect to the substrate along a third axis (e.g., the axis 1244 shown in FIG. 12D) that is substantially parallel to the first axis (e.g., the axis 1240 in FIG. 12B). In some implementations, the first mask position is adjusted by a length (e.g., 650 nm) such that the adjusted positions of the apertures of the first mask do not overlap with corresponding adjacent apertures (along the axis 1244) of the first mask, and such that the adjusted positions of the apertures of the first mask overlap with earlier positions (e.g., the positions indicated by 1208 in FIG. 12C) of the respective apertures of the first mask. The method further comprises, after adjusting the positioning of the first mask along the third axis, exposing (1320) the resist layer to the radiant energy for a fourth time, less than the first exposure time. The sum of the first time and the fourth time is equal to, or greater than, the first exposure time such that, after exposing for the first time and the fourth time, the first set of rows and the first set of columns of the resist layer is fully exposed to the radiant energy. For example, in FIG. 12D, exposing the resist layer 1108 to the radiant energy (e.g., as explained above in reference to FIGS. 4A-4E) for a period less than half of a full exposure time for a fourth time results in parts of the resist layer 1108 partially exposed (e.g., the regions 1210), and parts of the resist layer 1108 fully exposed (e.g., the regions 1206-6) because the corresponding regions were partially exposed two times, according to some implementations. The fully exposed regions 1206-2, 1206-4, and 1206-6 constitute the first set of rows (e.g., the rows 1220-2, 1220-4, 1220-6, and 1220-8 of FIG. 12E) and the first set of columns (e.g., the columns 1230-2, 1230-4, 1230-6, and 1230-8), according to some implementations.

The method 1300 further comprises forming (1322) row and column openings in the substrate by removing portions of the dielectric layer and the substrate corresponding to the fully exposed portions of the resist layer. In some implementations, removing the fully exposed portions of the resist layer is performed by using a developer solution. In some implementations, the substrate is planar. For example, in FIG. 12E (an isometric view of the FIG. 12D), portions of the dielectric layer and the substrate corresponding to the fully exposed portions of the resist layer (the rows 1220-2, 1220-4, 1220-6, and 1220-8, and the columns 1230-2, 1230-4, 1230-6, and 1230-8) are removed thereby forming openings, according to some implementations.

The method 1300 further comprises creating (1324) sub-lithographic isolation regions by depositing a dielectric material in the row and column openings in the substrate. In some implementations, this step includes performing etching in the openings (sometimes called trenches). The sub-lithographic isolation regions allow for a greater device density of devices (e.g., sub-lithographic devices) compared to when devices are fabricated without the sub-lithographic isolation regions. As illustrated in FIG. 12E, the active area (indicated by the region between the columns 1230-2 and 1230-4, the region between the columns 1230-4 and 1230-6, and the region between the columns 1230-6 and 1230-8) is increased. For example, the region 1250 (highlighted for emphasis) indicates an active area (e.g., 1300 nm by 1300 nm) that is larger than the active area shown in the initial layout shown in FIG. 12A (e.g., w1200 by 11200), according to some implementations. More importantly, the isolation regions (indicated by the columns 1230-2, 1230-4, 1230-6, and 1230-8, and the rows 1220-2, 1220-4, 1220-6, and 1220-8) are thinner (e.g., 200 nm by 1300 nm). Thus, sub-lithographic isolation regions separate larger active areas.

In some implementations, obtaining the substrate with the dielectric layer and the resist layer comprises depositing the dielectric layer over the substrate, and depositing the resist layer over the dielectric layer. For example, in FIG. 11A, the dielectric layer 1104 is layered over the substrate 1102, and the resist layer 1106 is layered over the dielectric layer 1104, according to some implementations.

In some implementations, prior to depositing the resist layer, depositing a protective layer (sometimes called a hard mask; e.g., a nitride layer) over the dielectric layer such that cavities are not formed in partially exposed regions of the resist layer, and removing the protective layer after depositing the dielectric material (e.g., oxide) in the row and column openings in the substrate. An example process for depositing and removing a hard mask layer is described above in reference to FIG. 6.

In some implementations, the dielectric material deposited in the row and column openings in the substrate corresponds to a material of the dielectric layer (e.g., the layer 1104).

In some implementations, the method 1300 further comprises depositing a material corresponding to the dielectric layer (e.g., the layer 1104) in the row and column openings in the substrate prior to depositing the dielectric material.

In some implementations, the lithographic size constraint corresponds to a first isolation width, and each of the plurality of isolation regions has a width that is less than the first isolation width.

In some implementations, the method 1300 further comprises polishing (not shown) of the dielectric material deposited in the row and column openings in the substrate.

In some implementations, the method 1300 further comprises, after fabricating the plurality of isolation regions, depositing a second resist layer having a second exposure time. The method 1300 also includes fabricating respective sub-lithographic elements for each of the plurality of devices, comprising a sequence of steps for each device of the plurality of devices. The sequence of steps includes determining an element size and positioning for the sub-lithographic element. The position includes a first corner and a second corner diagonally opposed to the first corner. The positioning for the sub-lithographic element corresponds to a first portion of a second resist layer. The sequence of steps also includes positioning a second mask over the substrate, the second mask including a first aperture corresponding to a first region of the second resist layer aligned with the first corner, the first region including the first portion and having a size larger than the element size. The sequence of steps further includes after positioning the first mask, exposing the second resist layer to the radiant energy for a fourth time, less than the second exposure time, to partially expose the first region. The sequence of steps further includes adjusting positioning of the second mask with respect to the substrate such that the first aperture in the second mask corresponds to a second region of the second resist layer aligned with the second corner, the second region partially overlapping the first region. The overlap of the first region and the second region is the first portion. The sequence of steps further includes, after adjusting the positioning of the second mask, exposing the second resist layer to the radiant energy for a fifth time, less than the second exposure time. The sum of the fourth time and the fifth time is equal to, or greater than, the second exposure time such that, after exposing for the fourth time and the fifth time, the first portion of the second resist layer is fully exposed to the radiant energy. The sequence of steps further includes forming an opening in the second resist layer by removing the fully exposed first portion, and depositing material for the sub-lithographic element within the opening in the second resist layer. An example process for fabricating sub-lithographic devices is described above in reference to FIGS. 1A-1D and 4A-4F, according to some implementations.

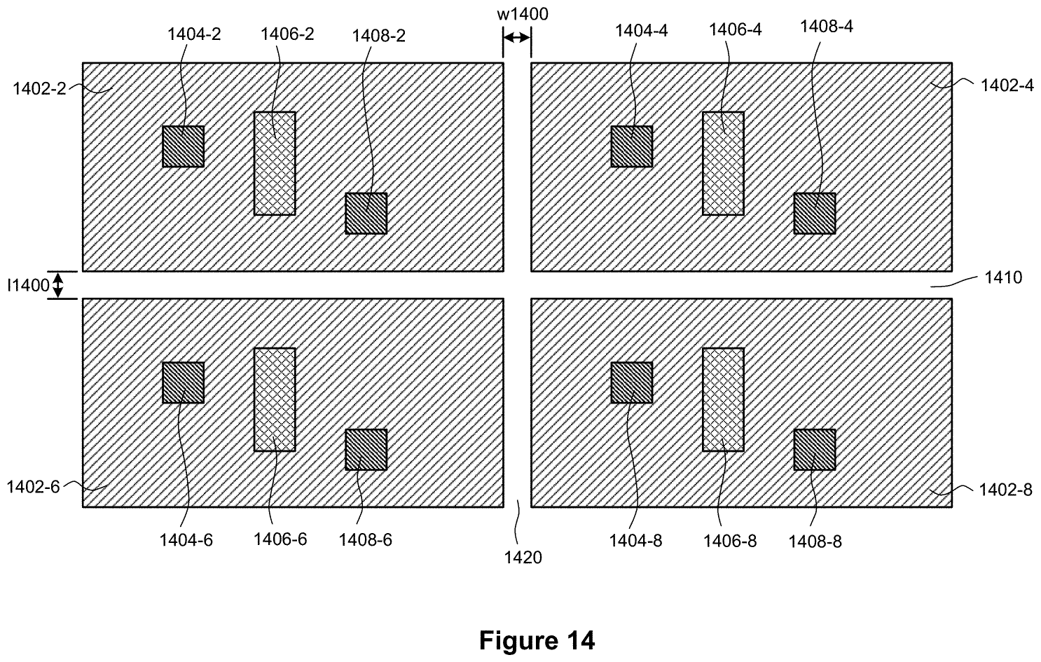

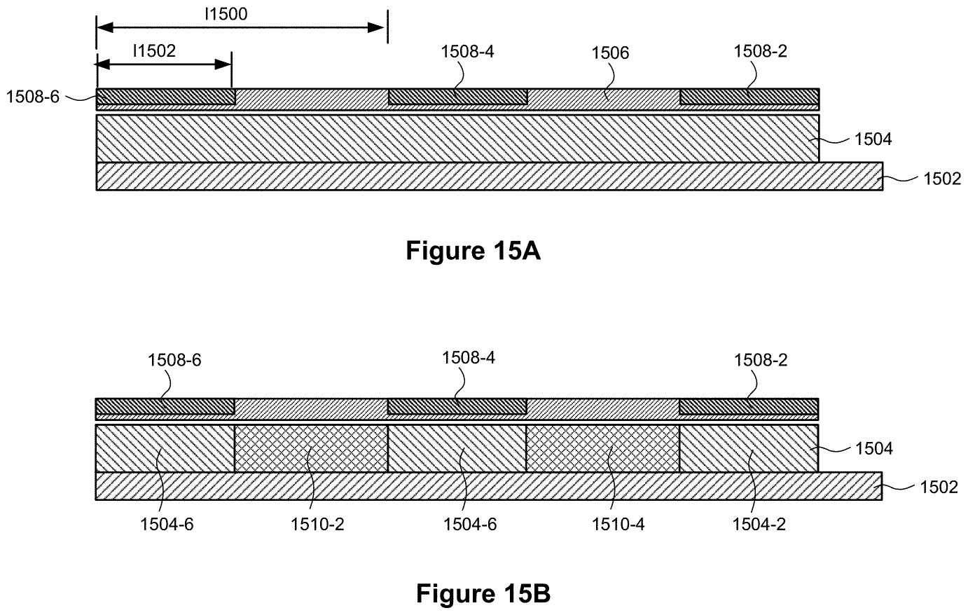

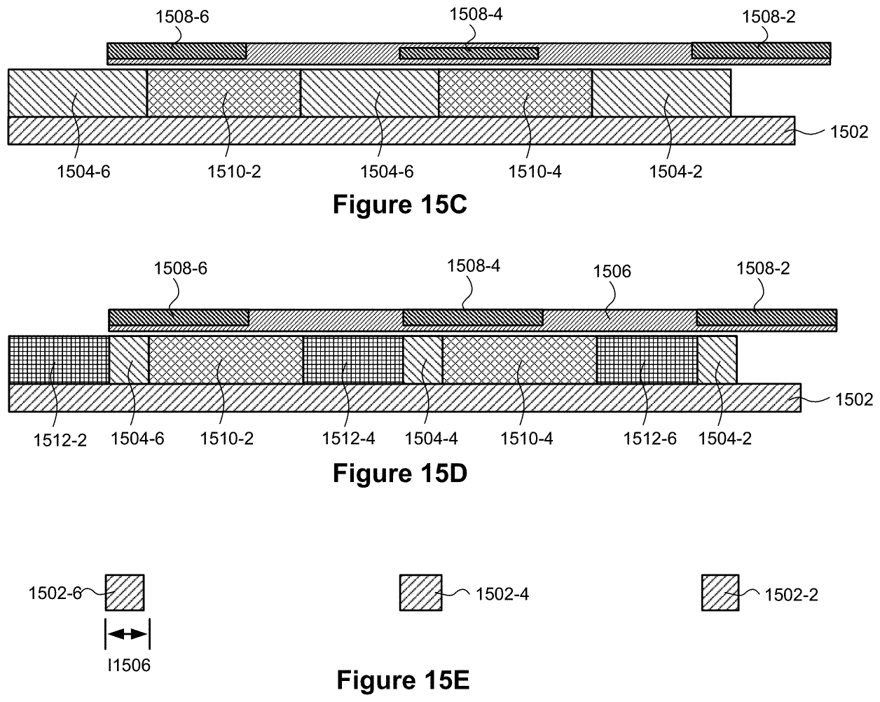

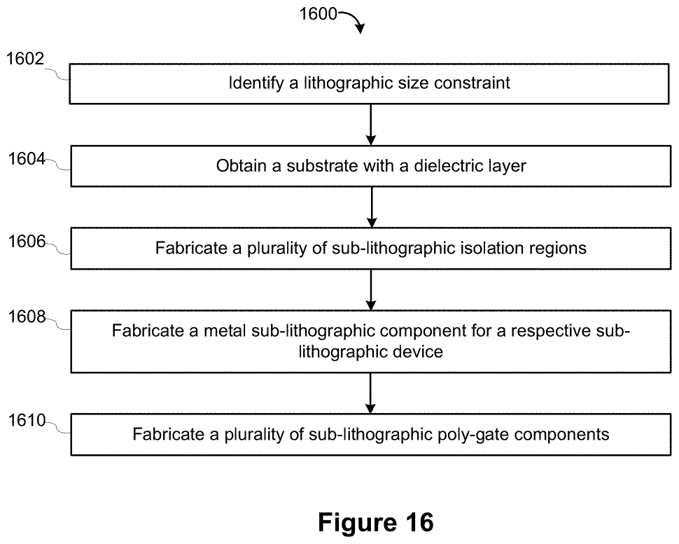

FIG. 14 shows a schematic diagram of a representative layout for fabricating a plurality of sub-lithographic devices with reduced isolation regions there between, in accordance with some implementations. FIGS. 15A-15E illustrate a representative process for fabricating a plurality of sub-lithographic devices with reduced isolation regions there between, in accordance with some implementations. FIGS. 14 and 15A-15E are described below in reference to FIG. 16.

FIG. 16 illustrates a flowchart of a method 1600 for fabricating a plurality of sub-lithographic devices with reduced isolation regions there between in accordance with some implementations. The method 1600 comprises identifying (1602) a lithographic size constraint. For example, in FIG. 1A, 112 indicates a lithographic size constraint for a lithographic process, and in FIG. 15A, 11500 indicates a lithographic size constraint, according to some implementations. The method 1600 further comprises obtaining (1604) a substrate with a dielectric layer. The method 1600 further comprises fabricating (1606) a plurality of sub-lithographic isolation regions (e.g., the row 1410 and the column 1420 of FIG. 14). Each sub-lithographic isolation region has a dimension that is less than the lithographic size constraint. For example, in FIG. 14, the length l1400 of the row 1410 and the width w1400 of the column 1420 are less than the lithographic size constraint. The plurality of isolation regions is configured to electrically-insulate the plurality of sub-lithographic devices from one another. For example, in FIG. 14, the devices 1402-2 and 1402-4 are insulated from one another by the column 1420, the devices 1402-6 and 1402-8 are insulated from one another by the column 1420, the devices 1402-2 and 1402-6 are insulated from one another by the row 1410, and the devices 1402-4 and 1402-8 are insulated from one another by the row 1410, according to some implementations. A method 1300 for fabricating sub-lithographic isolation regions is described above in reference to FIGS. 11, 12A-12E, and 13A-13B, according to some implementations. FIG. 15A indicates a mask 1506 with portions 1508-6, 1508-4, and 1508-2 that block radiant energy when a resist layer with sensitivity to the radiant energy is exposed to the radiant energy, according to some implementations.

The method 1600 further comprises fabricating (1608) a metal sub-lithographic component for a respective sub-lithographic device. The metal sub-lithographic component has a dimension that is less than the lithographic size constraint. For example, in FIG. 14, the method 1600 includes fabricating the component 1406-2 of the device 1402-2, the component 1406-4 of the device 1404-4, the component 1406-6 of the device 1404-6, and the component 1406-8 of the device 1404-8, according to some implementations. The components have a size (e.g., a length) that is less than the lithographic size constraint.

The method 1600 further includes fabricating (1610) a plurality of sub-lithographic poly-gate components by performing a sequence of steps. For example, in FIG. 14, the method 1600 includes fabricating the poly-gate components 1404-2 and 1408-2 of the device 1402-2, the poly-gate components 1404-4 and 1408-4 of the device 1402-4, the poly-gate components 1404-6 and 1408-6 of the device 1402-6, and the poly-gate components 1404-8 and 1408-8 of the device 1402-8, according to some implementations.

The sequence of steps for fabricating (1610) the plurality of sub-lithographic poly-gate components comprises depositing a poly layer (e.g., the layer 1502, FIG. 15A) over the dielectric layer (not shown). The sequence of steps further comprises depositing a first resist layer (e.g., the layer 1504) over the poly layer. The first resist layer consists of first regions (e.g., the regions 1510-2 and 1510-4, FIG. 15D), second regions (e.g., the regions 1512-2, 1512-4, and 1512-6, FIG. 15D), and third regions (e.g., regions 1504-6, 1504-4, and 1504-2). The third regions correspond to respective sub-lithographic poly-gate components. The sequence of steps further comprises exposing the first regions of the first resist layer (e.g., the regions 1510-2 and 1510-4 of the resist layer 1504 are exposed in FIG. 15B), exposing the second regions of the first resist layer (e.g., the regions 1512-2, 1512-4, and 1512-6 of the resist layer 1504 are exposed in FIG. 15D after adjusting the mask as shown in FIG. 15C), forming openings in the first resist layer by removing fully-exposed regions of the first resist layer (e.g., the regions 1512-2, 1510-2, 1512-4, 1510-4, and 1512-6 are fully exposed and removed), and forming the poly-gate components by removing portions of the poly layer that correspond to the openings in the first resist layer. For example, in FIG. 15E, the components 1502-6, 1502-4, and 1502-2 are formed by removing portion of the poly layer 1502 that correspond to openings in the first resist layer. In some implementations, removing the portions of the poly layer is performed by etching the poly layer. As illustrated in FIG. 15E, the size of each sub-lithographic poly-gate component 11506 that can be fabricated with the method 1600 is substantially smaller than the length 11502 (example size of a component that can be fabricated with a lithographic device; a lithographic size constraint) shown in FIG. 15A, according to some implementations.

In some implementations, fabricating the plurality of isolation regions comprises depositing a second resist layer over the substrate (e.g., not directly on top of the substrate but over one or more intermediate layers), identifying the plurality of sub-lithographic isolation regions comprising a first set of rows and a first set of columns, partially exposing first regions of the second resist layer, partially exposing second regions of the second resist layer. The overlap between the first regions and the second regions of the second resist layer is the first set of columns. Partially exposing the first regions of the second resist layer and partially exposing the second regions of the second resist layer comprises fully exposing the first set of columns. Fabricating the plurality of isolation regions further comprises partially exposing third regions of the second resist layer. Overlap between the first regions and the third regions of the second resist layer is the first set of rows, and partially exposing the first regions of the second resist layer and partially exposing the third regions of the second resist layer comprises fully exposing the first set of rows. Fabricating the plurality of isolation regions further comprises removing fully exposed portions of the second resist layer including the first set of rows and the first set of columns, forming row and column openings in the substrate by removing portions of the dielectric layer and the substrate corresponding to the removed portions of the second resist layer, and creating the plurality of sub-lithographic isolation regions by depositing a dielectric material in the row and column openings in the substrate.

In some implementations, the second resist layer has sensitivity to a radiant energy and has a first exposure time, partially exposing first regions of the second resist layer comprises exposing the second resist layer to the radiant energy for a first time, less than the first exposure time, partially exposing second regions of the second resist layer comprises exposing the second resist layer to the radiant energy for a second time, less than the first exposure time, partially exposing third regions of the second resist layer comprises exposing the second resist layer to the radiant energy for a third time, less than the first exposure time. The sum of the first time and the second time is equal to, or greater than, the first exposure time such that, after exposing for the first time and the second time, the first set of columns of the second resist layer is fully exposed to the radiant energy. The sum of the first time and the third time is equal to, or greater than, the first exposure time such that, after exposing for the first time and the third time, the first set of rows of the second resist layer is fully exposed to the radiant energy.

In some implementations, the method 1600 further comprises selecting the first time to be at least half of the first exposure time. In some implementations, the method 1600 further comprises, prior to depositing the second resist layer, depositing a protective layer (e.g., a hard mask layer, such as a nitride layer) over the dielectric layer such that cavities are not formed in partially exposed regions of the second resist layer, and removing the protective layer after depositing the dielectric material in the row and column openings in the substrate.

In some implementations, fabricating the metal sub-lithographic component comprises depositing a third resist layer over the dielectric layer, partially exposing a first region of the third resist layer, partially exposing a second region of the third resist layer. The overlap between the first region and the second region of the third resist layer is a first portion that corresponds to the metal sub-lithographic component. Partially exposing the first region of the third resist layer and partially exposing the second region of the third resist layer comprises fully exposing the first portion. Fabricating the metal sub-lithographic component further comprises forming an opening in the third resist layer by removing the fully exposed first portion, forming a component opening in the dielectric layer by removing portions of the dielectric layer corresponding to the opening in the third resist layer, and depositing material for the metal sub-lithographic component within the component opening in the dielectric layer.

In some implementations, the method 1600 further comprises determining a component size and positioning for the metal sub-lithographic component, including determining that the component size is less than the lithographic size constraint. The position includes a first corner and a second corner diagonally opposed to the first corner.

In some implementations, partially exposing the first region of the third resist layer comprises positioning a first mask over the substrate, the first mask including a first aperture corresponding to the first region of the third resist layer aligned with the first corner, the first region including the first portion and having a size larger than the component size. Partially exposing the first region of the third resist layer further comprises, after positioning the first mask, exposing the third resist layer to a radiant energy for a first time, less than a first exposure time, to partially expose the first region. The third resist layer has a sensitivity to the radiant energy, and the third resist layer has the first exposure time. Partially exposing the first region of the third resist layer further comprises adjusting positioning of the first mask with respect to the substrate such that the first aperture in the first mask corresponds to the second region of the third resist layer aligned with the second corner, and, after adjusting the positioning of the first mask, exposing the third resist layer to the radiant energy for a second time, less than the first exposure time. The sum of the first time and the second time is equal to, or greater than, the first exposure time such that, after exposing for the first time and the second time, the first portion of the resist layer is fully exposed to the radiant energy.

In some implementations, the method 1600 further comprises identifying a minimum pitch based on the lithographic size constraint, determining a second pitch, greater than the minimum pitch, based on a size and positioning of the metal sub-lithographic component. The second pitch is selected to prevent undesirable overlap when adjusting the positioning of the first mask, and generating the first mask based on the second pitch.

Although some of various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages could be implemented in hardware, firmware, software or any combination thereof.

It will also be understood that, although the terms first, second, etc., are, in some instances, used herein to describe various elements, these elements should not be limited by these terms. These terms are only used to distinguish one element from another. For example, a first device could be termed a second device, and, similarly, a second device could be termed a first device, without departing from the scope of the various described implementations. The first device and the second device are both electronic devices, but they are not the same device unless it is explicitly stated otherwise.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific implementations. However, the illustrative discussions above are not intended to be exhaustive or to limit the scope of the claims to the precise forms disclosed. Many modifications and variations are possible in view of the above teachings. The implementations were chosen in order to best explain the principles underlying the claims and their practical applications, to thereby enable others skilled in the art to best use the implementations with various modifications as are suited to the particular uses contemplated.

1. A method of fabricating a sub-lithographic device, comprising:
depositing a resist layer on a substrate, the resist layer having a sensitivity to a radiant energy, wherein the resist layer has a first exposure time, and wherein a position for a first component of a plurality of components corresponds to a first portion of the resist layer;
positioning a first mask over the substrate, the first mask including a first aperture corresponding to a first region of the resist layer aligned with a first corner, the first region including the first portion and having a size larger than a component size for the first component, and the position includes the first corner and a second corner diagonally opposed to the first corner;
after positioning the first mask, exposing the resist layer to the radiant energy for a first time, less than the first exposure time, to partially expose the first region;
adjusting positioning of the first mask with respect to the substrate such that the first aperture in the first mask corresponds to a second region of the resist layer aligned with the second corner, the second region partially overlapping the first region, wherein the overlap of the first region and the second region is the first portion of the resist layer;
after adjusting the positioning of the first mask, exposing the resist layer to the radiant energy for a second time, less than the first exposure time, wherein sum of the first time and the second time is equal to, or greater than, the first exposure time such that, after exposing for the first time and the second time, the first portion of the resist layer is fully exposed to the radiant energy;
forming an opening in the resist layer by removing the fully exposed first portion of the resist layer; and
depositing material for the first component within the opening in the resist layer.

2. The method of claim 1, further comprising:
determining a second pitch based on the component size and positioning of each of the plurality of components, wherein the second pitch is selected to prevent undesirable overlap when adjusting the positioning of the first mask; and
generating the first mask based on the second pitch.

3. The method of claim 1, further comprising producing the first mask for fabrication of a plurality of sub-lithographic devices, including the sub-lithographic device, comprising:
associating the first aperture in the first mask to the sub-lithographic device;
associating a second aperture in the first mask to a second sub-lithographic device, distinct from the sub-lithographic device;
determining a first area of the resist layer that will be at least partially exposed via the first aperture and adjustments to the first mask positioning during fabrication of the plurality of components;
determining a second area of the resist layer that will be at least partially exposed via the second aperture and the adjustments to the first mask during fabrication of a second plurality of components for the second sub-lithographic device;
determining a pitch for the first mask based on a spacing between the plurality of sub-lithographic devices, the pitch sufficient to prevent overlap of the first area and the second area; and
generating the first mask with the first aperture, the second aperture, and the determined pitch.

4. The method of claim 1, further comprising selecting the first time to be at least half of the first exposure time.

5. The method of claim 1, further comprising depositing a hard mask layer, such that cavities are not formed in partially exposed regions of the resist layer.

6. The method of claim 1, wherein removing the fully exposed resist region is performed by using a developer solution.

7. The method of claim 1, further comprising:
prior to depositing the resist layer, depositing a dielectric layer over the substrate;
after forming the opening in the resist layer, etching a corresponding opening in the dielectric layer; and
removing the remaining resist layer;
wherein depositing the material comprises depositing the material in the opening of the dielectric layer.

8. The method of claim 1, wherein adjusting positioning of the first mask comprises one or more of: stepping the first mask along a first axis, and stepping the first mask along a second axis.

9. The method of claim 1, further comprising:
removing the first mask and positioning a second mask over the substrate, the second mask including a third aperture corresponding to a third region of the resist layer, the third region including a second portion of the resist layer and having a size larger than a component size for a second component of the plurality of components, wherein the positioning for the second component corresponds to the second portion; and
after positioning the second mask, exposing the resist layer to the radiant energy for a third time, less than the first exposure time, to partially expose the third region.

10. The method of claim 1, wherein the substrate is planar.

11. A sub-lithographic device, comprising:
a plurality of components, including a first component fabricated by a method comprising the steps of:
depositing a resist layer on a substrate, the resist layer having a sensitivity to a radiant energy, wherein the resist layer has a first exposure time, and wherein a position for a first component of a plurality of components corresponds to a first portion of the resist layer;
positioning a first mask over the substrate, the first mask including a first aperture corresponding to a first region of the resist layer aligned with a first corner, the first region including the first portion and having a size larger than a component size for the first component, and the position includes the first corner and a second corner diagonally opposed to the first corner;
after positioning the mask, exposing the resist layer to the radiant energy for a first time, less than the first exposure time, to partially expose the first region;
adjusting positioning of the first mask with respect to the substrate such that the first aperture in the first mask corresponds to a second region of the resist layer, the second region partially overlapping the first region, wherein the overlap of the first region and the second region is the first portion of the resist layer;
after adjusting the positioning of the first mask, exposing the resist layer to the radiant energy for a second time, less than the first exposure time, wherein sum of the first time and the second time is equal to, or greater than, the first exposure time such that, after exposing for the first time and the second time, the first portion of the resist layer is fully exposed to the radiant energy;
forming an opening in the resist layer by removing the fully exposed first portion of the resist layer; and
depositing material for the first component within the opening in the resist layer.

12. The method of claim 1, wherein a smallest dimension of the component is less than a predefined minimum feature size that can be defined using the lithographic process.
